(19) United States
(12) Patent Application Publication
(10) Pub. No.: US 2026/0164918 A1
(43) Pub. Date: Jun. 11, 2026

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Kwang Jong KIM, Paju-si (KR); Do Yeong ` SHIN, Paju-si (KR); Su Min GWON, Paju-si (KR)

(73) Assignee: LG Display Co., Ltd., Seoul (KR)

(21) Appl. No.: 19/376,608

(22) Filed: Oct. 31, 2025

(30) Foreign Application Priority Data
Dec. 11, 2024 (KR) 10-2024-0183996

(51) Int. Cl. H10K 50/11; H10K 59/35; H10K 101/40

(52) U.S. Cl. CPC H10K 50/11; H10K 59/353; H10K 2101/40

(57) ABSTRACT

A light emitting device and a light emitting display device including the same are discussed. The light emitting device can include a first electrode and a second electrode facing each other, and a first common layer, a first light emitting layer and a second common layer disposed between the first electrode and the second electrode. The first light emitting layer is divided into an odd number of layers, where the odd-numbered layers of the first light emitting layer contain a first host and a first dopant, and the even-numbered layers of the first light emitting layer contain a second host and the first dopant. Further, the first host has a triplet energy level higher than that of the second host. The first common layer and the second common layer contact a first layer and a last layer containing the first host and the first dopant, respectively.

### CROSS-REFERENCE TO RELATED APPLICATIONS

This application claims priority to Korean Patent Application No. 10-2024-0183996, filed in the Republic of Korea on Dec. 11, 2024, which is hereby expressly incorporated by reference as if fully set forth herein.

### BACKGROUND

### Technical Field

The present disclosure relates to a light emitting device with improved efficiency and lifespan, and a light emitting display device including the same.

### Discussion of the Related Art

With the advent of the information society, displays for visually expressing electrical information signals have rapidly developed. In response to this need, a variety of display devices with excellent performance such as slimness, low weight, and low power consumption are being developed.

Among such light emitting devices, a light emitting display device that does not require a separate light source to realize compactness and clear color and has a light emitting device in a display panel has been considered as a competitive application.

The light emitting device can include an anode and a cathode facing each other as electrodes, a light emitting layer between the anode and the cathode, and a common layer for transferring holes and electrons to the light emitting layer.

The light emitting device can include various functional layers for serving a variety of functions, for example, in the common layer. The functional layers include a hole transport layer for transferring holes to the light emitting layer and the electron transport layer for transferring electrons to the light emitting layer.

Light emitting devices include color light emitting layers to express various colors. The efficiency and lifespan characteristics of the color light emitting layers are different and development of a different device structure is needed for each color light emitting layer.

In addition, research is being conducted on the application of light emitting devices including color light emitting layers with relatively short lifespans to ensure uniform color display of display devices.

### SUMMARY OF THE DISCLOSURE

Accordingly, the present disclosure is directed to a light emitting device and a light emitting display device including the same that substantially obviate one or more problems due to limitations and disadvantages of the related art.

It is one object of the present disclosure to provide a light emitting device and a light emitting display device that include a plurality of light emitting layers with improved efficiency and reduced driving voltage.

It is another object of the present disclosure to provide a light emitting device and a light emitting display device with improved efficiency and lifespan.

It is another object of the present disclosure to provide a light emitting device and a light emitting display device that is imparted with improved efficiency and lifespan through a design in which a plurality of light emitting stacks have different multilayered light emitting layer structures.

It is another object of the present disclosure to provide a light emitting display device that includes a blue light emitting device with improved efficiency and lifespan to provide color stability without color change over time.

Additional advantages, objects, and features of the invention will be set forth in part in the description which follows and in part will become apparent to those having ordinary skill in the art upon examination of the following or can be learned from practice of the invention. The objectives and other advantages of the invention can be realized and attained by the structure particularly pointed out in the written description and claims hereof as well as the appended drawings.

To achieve these objects and other advantages and in accordance with the purpose of the disclosure, as embodied and broadly described herein, a light emitting device includes a first electrode and a second electrode facing each other, and a first common layer, a first light emitting layer and a second common layer between the first electrode and the second electrode, wherein the first light emitting layer is divided into an odd number of layers, odd-numbered layers of the first light emitting layer contain a first host and a first dopant, and the even-numbered layers of the first light emitting layer contain a second host and the first dopant, the first host has a triplet energy level higher than that of the second host, and the first common layer and the second common layer contact a first layer and a last layer containing the first host and the first dopant, respectively.

In another aspect of the present disclosure, a light emitting display device includes a substrate including a blue subpixel, a green subpixel, and a red subpixel, a pixel circuit provided in each of the blue subpixel, the green subpixel, and the red subpixel, a first electrode connected to a thin film transistor of the pixel circuit in each of the blue subpixel, the green subpixel, and the red subpixel, a second electrode facing the first electrode, and a first common layer and a second common layer disposed between the first electrode and the second electrode, wherein the blue subpixel includes a first blue light emitting layer containing a blue dopant between the first common layer and the second common layer, the green subpixel includes a first green light emitting layer containing a green dopant between the first common layer and the second common layer, and the red subpixel includes a first red light emitting layer containing a red dopant between the first common layer and the second common layer, wherein the first blue light emitting layer is divided into an odd number of layers, odd-numbered layers of the first blue light emitting layer contain a first blue host and a first blue dopant, and even-numbered layers of the first blue light emitting layer contain a second blue host and the first blue dopant, the first blue host has a triplet energy level higher than that of the second blue host, and the first common layer and the second common layer at the blue subpixel contact a first layer and a last layer containing a first blue host and a first blue dopant, respectively.

It is to be understood that both the foregoing general description and the following detailed description of the present disclosure are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a light emitting device according to one or more embodiments of the present disclosure;

FIG. 2 is a cross-sectional view illustrating an example in which the light emitting layer of FIG. 1 has a three layer structure;

FIG. 3 is an energy band diagram of the light emitting layer and adjacent layers of FIG. 1;

FIG. 4 illustrates light emitting layers of Experimental Examples 1 and 2;

FIG. 5 is a graph showing the 95-lifespan of light emitting devices according to Experimental Examples 1 and 2;

FIG. 6 is a graph showing the luminance efficiency depending on the CIEy of the light emitting devices according to Experimental Examples 1 and 2;

FIG. 7 is a cross-sectional view illustrating an example in which the light emitting layer according to another embodiment of the present disclosure has a five-layer structure;

FIG. 8 is a cross-sectional view illustrating a light emitting device according to another embodiment of the present disclosure;

FIG. 9 is a cross-sectional view illustrating a light emitting device according to another embodiment of the present disclosure;

FIGS. 10A and 10B illustrate layered structures of the first blue light emitting layer and the second blue light emitting layer of FIG. 8 or 9, respectively, according to one embodiment of the present disclosure;

FIG. 11 is an example of an energy band diagram of the first blue light emitting stack of FIG. 8 or FIG. 9;

FIG. 12 is an example of an energy band diagram of the second blue light emitting stack of FIG. 8 or 9;

FIG. 13 is an example of a graph showing comparison in lifespan between Experimental Examples 4, 5, and 6;

FIG. 14 is an example of a graph showing comparison in lifespan between Experimental Examples 5 and 7;

FIG. 15 is an example of a graph showing comparison in lifespan between Experimental Examples 8 and 9;

FIG. 16 is a cross-sectional view illustrating light emitting devices of a red subpixel, a green subpixel, and a blue subpixel in the light emitting display device according to one embodiment of the present disclosure; and

FIG. 17 is a cross-sectional view illustrating a light emitting display device according to one embodiment of the present disclosure.

### DETAILED DESCRIPTION OF THE EMBODIMENTS

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Further, the term “can” fully encompasses all the meanings and coverages of the term “may” and vice versa.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, i.e., the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. All the components of each device/apparatus according to all embodiments of the present disclosure are operatively coupled and configured.

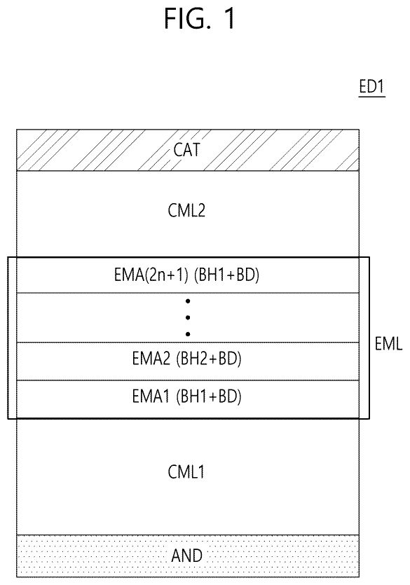

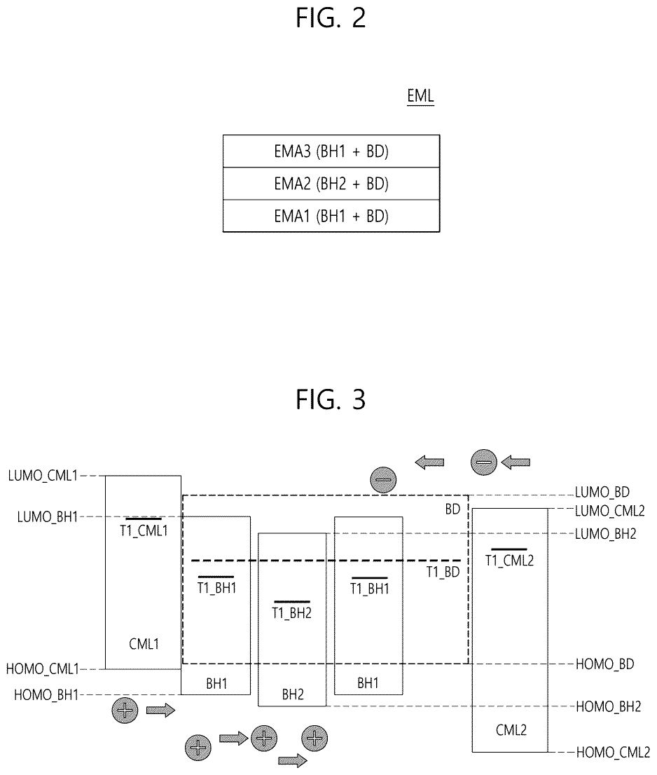

FIG. 1 is a cross-sectional view illustrating a light emitting device according to one embodiment of the present disclosure. FIG. 2 is a cross-sectional view illustrating an example in which the light emitting layer of FIG. 1 has a three layer structure. FIG. 3 is an energy band diagram of the light emitting layer and adjacent layers of FIG. 1.

As shown in FIG. 1, the light emitting device ED1 according to one embodiment of the present disclosure includes a first electrode AND and a second electrode CAT facing each other, and a first common layer CML1, a light emitting layer EML, and a second common layer CML2 sequentially disposed between the first electrode AND and the second electrode CAT.

At least one of the first electrode AND and the second electrode CAT is transparent or semi-transparent, and light generated in the light emitting device ED1 is transmitted through the transparent or semi-transparent electrode. For example, when the first electrode AND includes a reflective electrode and the second electrode CAT includes a semi-transparent or transparent electrode, the light emitting device ED1 can be a top-emission type. As another example, when the first electrode AND includes a semi-transparent or transparent electrode and the second electrode CAT includes a reflective electrode, the light emitting device ED1 can be a bottom-emission type. As another example, the first electrode AND and the second electrode CAT can be transparent or semi-transparent electrode, so that the light emitting device ED1 can emit light in both directions.

The first electrode AND can function as an anode and the second electrode CAT can function as a cathode. The first electrode AND can be connected to the thin film transistor of the pixel circuit provided in each subpixel on the substrate. The second electrode CAT can be provided in common to each subpixel and can receive a common voltage signal at least from a non-active area.

The first common layer CML1 can include, for example, at least one of a hole injection layer, a hole transport layer, or an electron blocking layer. Each of the hole injection layer, the hole transport layer, and the electron blocking layer can be selected from a material that includes a hole transport material or a material that does not inhibit the flow of holes. The configuration of the first common layer CML1 contacting one side of the light emitting layer EML (the lower surface of the light emitting layer EML in FIG. 1) can be a hole transport layer or an electron blocking layer.

The second common layer CML2 can include, for example, at least one of a hole blocking layer, an electron transport layer, or an electron injection layer. The second common layer CML2 that contacts the other side of the light emitting layer EML (the upper surface of the light emitting layer EML of FIG. 1) can be a hole blocking layer or an electron transport layer. The hole blocking layer and the electron transport layer can each include an electron transport material or can be selected from a material that does not inhibit the flow of electrons.

The light emitting device ED1 of the embodiments of the present disclosure includes at least one light emitting layer EML including a plurality of layers, and the number of layers constituting the light emitting layer EML is an odd number, as shown in FIGS. 1 to 3.

In addition, odd-numbered layers (EMA1, EMA3, . . . , EMA(2n+1), wherein n is 1 or more) of the light emitting layer EML include a first host BH1 and a dopant BD of the same material, and even-numbered layers (EMA2, . . . , EMA(2n)) include a second host BH2 having at least a difference in triplet energy level from the first host BH1 and a dopant BD.

The first layer EMA1 of the light emitting layer EML and the last layer (EMA (2n+1)) of the light emitting layer EML each include the same first host BH1 and dopant BD.

For example, the light emitting layer EML can be a light emitting layer that emits blue light. For this purpose, the dopant BD can be a fluorescent dopant having an emission peak at a blue wavelength, for example, a wavelength of 430 nm to 495 nm and can also be a thermally activated delayed fluorescent dopant (TADF).

Holes transferred from the first common layer CML1 to the light emitting layer EML and electrons transferred from the second common layer CML2 to the light emitting layer EML recombine in the light emitting layer EML and singlet excitons and triplet excitons can be generated at a ratio of 1:3. Here, singlet excitons generated in the light emitting layer EML can fluoresce as the energy thereof drops to the ground state from a low singlet energy level S1_BD of a dopant BD in the light emitting layer EML. The dopant BD is present in an equal amount with respect to the first host BH1 in each odd layer (EMA1, EMA3, . . . , EMA(2n+1)) of the light emitting layer EML, and is present in an equal or similar amount with respect to the second host BH2 in each even layer (EMA2, . . . , EMA(2n)). In addition, in order to facilitate energy transfer of the singlet exciton in each layer, the singlet energy level S1_BH1 of the first host BH1 and the singlet energy level S1_BH2 of the second host BH2 can each be greater than the singlet energy level of the dopant BD.

In addition, the first host BH1 present in the odd layers (EMA1, EMA3, . . . EMA(2n+1)) and the second host BH2 present in the even layers (EMA2, . . . ., EMA(2n)) have differences in triplet energy levels. As shown in FIG. 3, the triplet energy level T1_BH1 of the first host BH1 is greater than the triplet energy level T1_BH2 of the second host BH2. In addition, the triplet energy level T1_BD of the dopant BD is greater than the triplet energy level T1_BH1 of the first host BH1.

For example, the first host BH1, the second host BH2, and the dopant BD, which are components contained in the light emitting layer EML, have the following relationship in triplet energy levels T1.

$$T1\_BD > T1\_BH1 > T1\_BH2$$

As described above, the first layer EMA1 and the last layer (EMA(2n+1)) of the light emitting layer EML contain the first host BH1 and the dopant BD of the same material. The second host BH2 having a lower triplet energy level T1_BH2 and the dopant BD are contained in the even-numbered layers (EMA2, . . . , EMA(2n)) in the light emitting layer EML.

Here, the first common layer CML1 can include a hole transport layer HTL contacting the first layer EMA1 of the light emitting layer EML, and the second common layer CML2 can include an electron transport layer ETL contacting the last layer EMA(2n+1) of the light emitting layer EML. The first common layer CML1 and the second common layer CML2 can have triplet energy levels T1_CML1 and T1_CML2, respectively, greater than the triplet energy levels T1_BH1, T1_BH2 and T1_BD of all materials BH1, BH2, and BD in the light emitting EML.

The lowest unoccupied molecular orbital (LUMO) energy level LUMO_BD of the dopant BD is higher than the LUMO energy level of each of the first and second hosts (LUMO_BD>LUMO_BH1, LUMO_BD>LUMO_BH2). In addition, the second common layer CML2 can have a LUMO energy level LUMO_CML2 lower than the LUMO energy level LUMO_BD of the dopant BD (LUMO_BD>LUMO_CML2). Electrons injected from the second common layer CML2 through the LUMO energy level LUMO_BD of the dopant BD are easily injected into the LUMO energy levels of the first and second hosts BH1 and BH2 in each layer of the light emitting layer.

The first common layer CML1 has a LUMO energy level LUMO_CML1 higher than the LUMO energy level LUMO_BD of the dopant BD (LUMO_CML1>LUMO_BD) and a HOMO energy level HOMO_CML1 lower than the highest occupied molecular orbital (HOMO) energy level HOMO_BD of the dopant BD (HOMO_BD>HOMO_CML1). The first common layer CML1 has a higher LUMO energy level LUMO_CML1 than the dopant BD, so that electrons transferred into the light emitting layer EML are confined within the light emitting layer EML and function to emit light. In addition, the HOMO energy level HOMO_BD of the dopant BD can be higher than the HOMO energy level HOMO_BH1, HOMO_BH2 of each of the first and second hosts (HOMO_BD>HOMO_BH1, HOMO_BD>HOMO_BH2). Furthermore, the HOMO energy level HOMO_BD of the dopant BD can also be higher than the HOMO energy level HOMO_CML2 of the second common layer CML2.

In the odd-numbered layers (EMA1, EMA3, . . . , EMA(2n+1)) including the first layer EMA1, electrons and holes recombine and fluorescence occurs immediately. In the even-numbered layers (EMA2, . . . , EMA(2n)) including the second layer EMA2, energy is transferred from the triplet energy level T1_BH1 of the first host BH1 of the odd-numbered layers (EMA1, EMA3, . . . , EMA(2n+1)) to the triplet energy level T1_BH2 of the second host BH2, and delayed luminescence is caused by the TTF (triplet-triplet fusion) mechanism in which triplet excitons collide, thus generating singlet excitons. For example, in the light emitting layer EML, odd-numbered layers (EMA1, EMA3, . . . , EMA(2n+1)) and even-numbered layers (EMA2, . . . EMA(2n)) are regionally separated by the distinction of host components BH1 and BH2 having differences in triplet energy levels (T1_BH1, T1_BH2), and odd-numbered layers (EMA1, EMA3, . . . , EMA(2n+1)) optimally perform immediate fluorescence, and even-numbered layers (EMA2, . . . , EMA(2n)) optimally perform delayed fluorescence.

FIGS. 2 and 3 are examples in which a multilayer structure of a light emitting layer EML is a three-layer structure. In the following experiments, the three-layer structured light emitting layer is a blue light emitting layer. The luminescence mechanism will be described based on the example of the three-layer structure.

In the first layer EMA1 and the third layer EMA3, electrons and holes recombine to generate singlet excitons and triplet excitons. Theoretically, singlet excitons and triplet excitons are generated in a ratio of 1:3. The singlet excitons generated in the odd-numbered layers EMA1 and EMA3 drop to the ground state from the singlet energy level S1_BD of the dopant BD, and fluorescence occurs immediately. In order to achieve more effective fluorescence within the first layer EMA1 and the third layer EMA3, the dopant BD can have a triplet energy level T1_BD higher than the triplet energy level T1_BH1 of the first host BH1 (T1_BD>T1_BH1), but can have a singlet energy level lower than the singlet energy level S1_BH1 of the first host BH1 (S1_BD<S1_BH1).

Singlet excitons generated by the recombination of holes and electrons within the first layer EMA1 and the third layer EMA3 are easily moved to the lower singlet energy level S1_BD of the dopant BD due to the lower singlet energy level of the dopant BD, thereby contributing to fluorescence of the dopant BD in the first layer EMA1 and the third layer EMA3.

In addition, the triplet excitons generated in the first layer EMA1 and the third layer EMA3 are not transferred to the dopant BD having a high triplet energy level in the odd layers EMA1 and EMA3, but are transferred to the first host BH1 having a lower triplet energy level than the dopant BD. Then, due to the relationship of the triplet energy level difference (T1_BH1>T1_BH2) between the first host BH1 and the second host BH2, the triplet excitons can be transferred molecularly from the first host BH1 of the odd layers EMA1 and EMA3 to the second host BH2 of the even layers EMA2 having a relatively lower triplet energy level, and the triplet excitons transferred to the even layers EMA2 collide with each other and generate singlet excitons by the TTF mechanism, thereby undergoing delayed fluorescence in the even layers EMA2. Here, in the even-numbered layer EMA2, singlet excitons and triplet excitons can be generated together within the second layer EMA2 by the supply of holes through the first common layer CML1 and the supply of electrons through the second common layer CML2, and the fluorescence by the singlet excitons generated in the even-numbered layer EMA2 itself, and delayed fluorescence caused by the TTF mechanism in which the triplet excitons directly generated by the second host BH2 and the triplet excitons that have crossed over the triplet energy level from the first host BH1 collide, thus generating singlet excitons, causes additional delayed fluorescence along with the immediate fluorescence in the even-numbered layer EMA2, thereby increasing luminous efficacy.

Meanwhile, when excitons in the light emitting layer are not used for light emission, they can interact with adjacent polarons and be quenched. Quenching can be a major factor of lowering the efficiency of the light emitting layer. In addition, when excitons that are not used for light emission accumulate at the interface contacting the first common layer CML1 or the second common layer CML2 in the light emitting layer, it can have a fatal effect on the lifespan of the light emitting device.

The light emitting device according to the embodiment of the present disclosure is designed such that the triplet energy level T1_BH1 of the first host BH1 provided in the odd-numbered layers EMA1 and EMA3 is higher than the triplet energy level T1_BH2 of the second host BH2 provided in the even-numbered layers EMA2, so that the energy transfer of the triplet excitons is easily performed from the first host BH1 to the second host BH2, and the triplet exciton that is not used for light emission is not accumulated in the region of the first layer EMA1 of the light emitting layer EML contacting the first common layer CML1 or the third layer EMA3, which is the last layer contacting the second common layer CML2, and the triplet excitons are transferred to the second layer EMA2, which is the even layer, by energy transfer due to the difference in triplet energy level between the first and second hosts BH1 and BH2, thereby maximizing TTF efficiency in the second layer EMA2, increasing the recycling rate of excitons, increasing luminous efficacy in the light emitting layer EML, and improving the lifespan.

Here, the even-numbered layers of the light emitting layer EML can include a second host BH2 with a lower triplet energy level, so that the triplet excitons can easily move to the even-numbered layers of the light emitting layer EML that are not adjacent to the first and second common layers CML1 and CML2 through energy transfer, thereby improving luminous efficacy.

On the other hand, when the light emitting layer is applied as a single emitting layer without a layer distinction, the lifespan degradation due to exciton accumulation is prominent at the interface between the light emitting layer and the common layer, especially at the interface where the light emitting layer and the hole transport layer come into contact.

Accordingly, the light emitting device ED1 according to the embodiment of the present disclosure generates light emission from odd-numbered layers (EMA1, EMA3, . . . EMA(2n+1)) and even-numbered layers (EMA2, . . . , EMA(2n)) within the light emitting layer EML, respectively, and in particular, the quenching of triplet excitons can be reduced or prevented, and triplet excitons can be used to the maximum extent for light emission, thereby improving luminous efficacy compared to a single-layer light emitting layer structure. In addition, since the triplet excitons do not remain in the odd layers (EMA1, EMA3, . . . , EMA(2n+1)) but rather move from the odd layers (EMA1, EMA3, . . . , EMA(2n+1)) to the even layers (EMA2, . . . , EMA(2n)) by energy transfer due to the triplet energy level difference (T1_BH1−T1_BH2>0) between the first and second hosts BH1 and BH2 of the odd layers (EMA1, EMA3, . . . , EMA(2n+1)) and the even layers (EMA2, . . . , EMA(2n)) and are recycled for delayed fluorescence, the quenched excitons are not generated at the interface between the first common layer CML1, the second common layer CML2, and the light emitting layer EML, thereby improving the lifespan of the light emitting layer EML.

Meanwhile, when the light emitting layer EML is divided into an odd number of layers, the odd layers contain a first host BH1 having a relatively large triplet energy level, and the even layers contain a second host BH2 having a relatively small triplet energy level, the luminescence intensity within the light emitting layer EML can be the largest at the interface between the first layer EMA1 and the second layer EMA2. In addition, the emission zone of the light emitting layer EML can be concentrated in the first layer EMA1 and the second layer EMA2. This is because the third layer EMA3 adjacent to the second common layer CML2 in the light emitting layer EML has a lower supply of holes than the first layer EMA1 and the second layer EMA2, and thus the generation rate of excitons generated by the recombination of electrons and holes can be lowered.

The luminescence intensity in the light emitting layer EML can vary depending on the recombination rate of holes and electrons. For example, the interface between the first layer EMA1 and the second layer EMA2 having a high recombination rate has the strongest luminescence intensity, and the recombination rate can gradually decrease with increasing distance from the interface between the first layer EMA1 and the second layer EMA2. In order to effectively secure the luminescence area, the thickness of the first layer EMA1 and the second layer EMA2 having a high recombination rate can be disposed to be greater than the thickness of the third layer EMA3.

The first host BH1 can be, for example, a compound including a pyrene derivative, such as a pyrene derivative.

The second host BH2 can be, for example, a compound including an anthracene derivative, such as an anthracene derivative.

The examples of compounds of the first and second hosts BH1 and BH2 are not limited to the examples described above, and when the first host BH1, the second host BH2, and the dopant BD have a relationship of T1_BD>T1_BH1>T1_BH2 in the triplet energy level T1, they can be changed to other compounds.

The dopant BD in the light emitting layer EML is a fluorescent dopant having an emission peak at a wavelength of 430 nm to 495 nm. For example, the dopant BD can include a boron-based dopant, as shown in the following Formulas 1 to 9, but this is merely provided as an example and the dopant in the embodiments of the present disclosure is not limited to the following materials. Any fluorescent dopant capable of fluorescence and delayed fluorescence, having an emission peak at a wavelength of visible light of 495 nm or less, and having a high triplet energy level can be used.

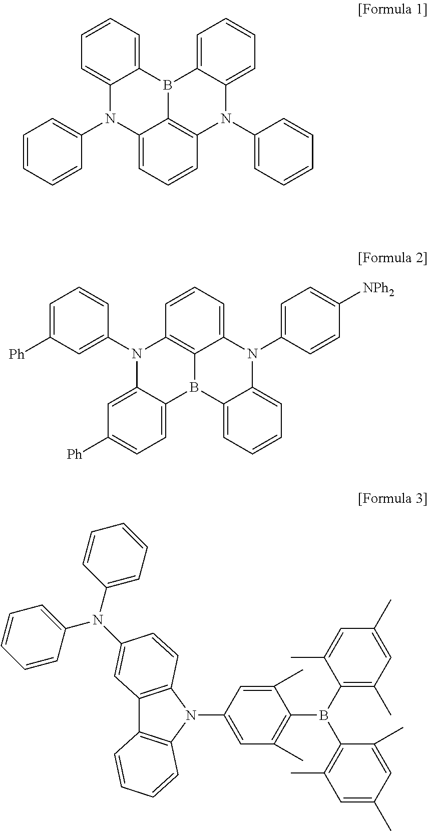

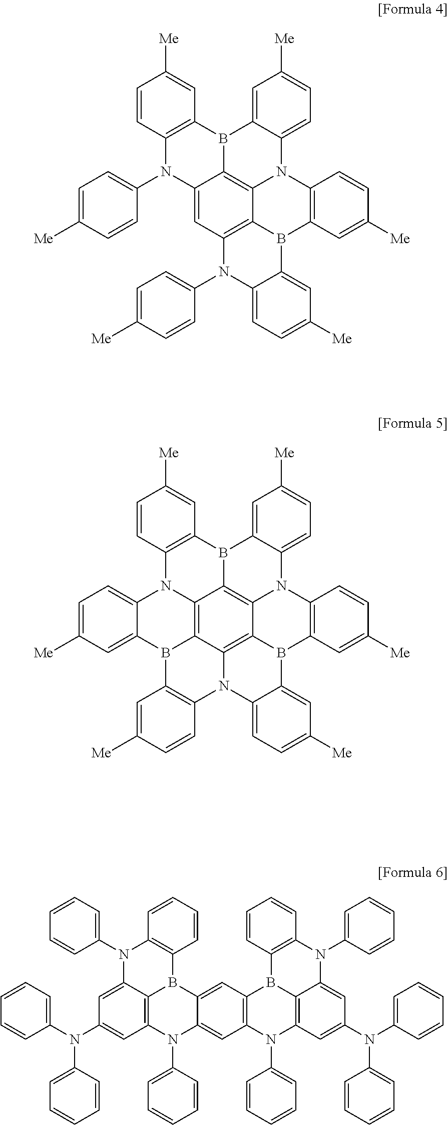 [SMILES: Cc1ccc(N2c3ccc(C)cc3B3c4cc(C)ccc4N4c5ccc(C)cc5B5c6cc(C)ccc6N(c6ccc(C)cc6)c6cc2c3c4c65)cc1 ; Cc1ccc2c(c1)B1c3cc(C)ccc3N3c4ccc(C)cc4B4c5cc(C)ccc5N5c6ccc(C)cc6B6c7cc(C)ccc7N2c2c1c3c4c5c26 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

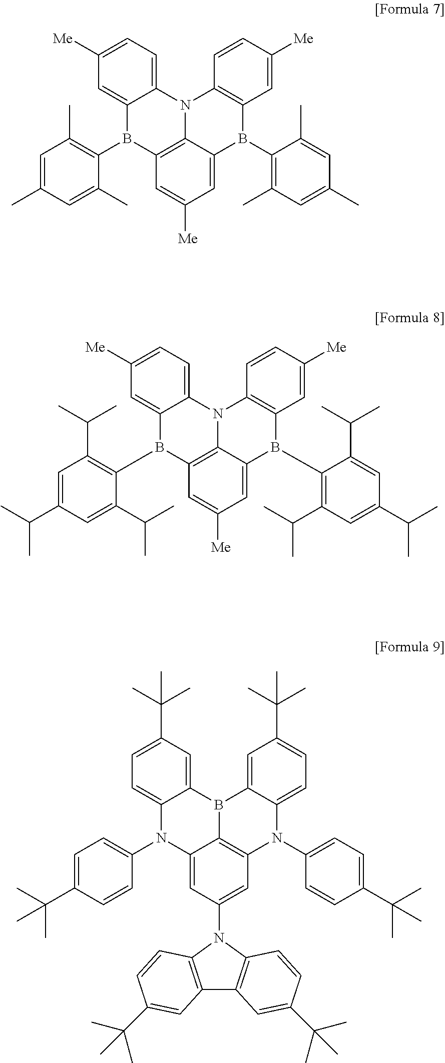

In addition, the triplet energy level of the dopant can be adjusted to be higher by changing the substituent in at least a part of any one of the compounds of Formulas 1 to 9 described above in the light emitting device according to the embodiment of the present disclosure.

Here, in the light emitting layer EML, the odd-numbered layers (EMA1, EMA3, . . . , EMA(2n+1)) include the first host BH1 and the dopant BD, and the even-numbered layers (EMA2, . . . , EMA(2n)) include the second host BH2 and the dopant BD.

The odd-numbered layers (EMA1, EMA3, . . . , EMA(2n+1)) and the even-numbered layers (EMA2, . . . , EMA(2n)) have differences in the host components. The odd-numbered layers (EMA1, EMA3, . . . , EMA(2n+1)) and the even-numbered layers (EMA2, . . . , EMA(2n)) each contain the first host BH1 and the second host BH2 in main amounts. The odd-numbered layers (EMA1, EMA3, . . . , EMA(2n+1)) contain 50 wt % or more of the first host BH1 and the even-numbered layers (EMA2, . . . , EMA(2n)) contain 50 wt % or more of the second host BH2. More preferably, the odd-numbered layers (EMA1, EMA3, . . . , EMA(2n+1)) can contain 70 wt % or more of the first host BH1 and the even-numbered layers (EMA2, . . . , EMA(2n)) can contain 70 wt % or more of the second host BH2.

More preferably, the first host BH1 can be present in an amount of 90 wt % or more in the odd-numbered layers (EMA1, EMA3, . . . , EMA(2n+1)), and the second host BH2 can be present in an amount of 90 wt % or more in the even-numbered layers (EMA2, . . . , EMA(2n)). In this case, the dopant BD can be present at 10 wt % or less in the odd-numbered layers (EMA1, EMA3, . . . , EMA(2n+1)) and the even-numbered layers (EMA2, . . . , EMA(2n)).

In some cases, the odd-numbered layers (EMA1, EMA3, . . . , EMA(2n+1)) can contain 90 wt % or more of the first host BH1 and 10 wt % or less of the dopant BD within the layer, and the even-numbered layers (EMA2, . . . , EMA(2n)) can contain 70 wt % or more of the second host BH2, 20 wt % or more of another host other than the second host BH2, and 10 wt % or less of the dopant BD. The triplet energy level of the additional host other than the second host BH2 present in the even-numbered layers (EMA2, . . . , EMA(2n)) can be lower than or equal to the triplet energy level of the first host BH1.

Among the components contained in the light emitting layer EML, the triplet energy level T1_BD of the dopant BD is the highest and the triplet energy level T1_BH1 of the first host BH1 present in the odd-numbered layers (EMA1, EMA3, . . . , EMA(2n+1)) is higher than the triplet energy level T1_BH2 of the second host BH2 present in the even-numbered layers (EMA2, . . . , EMA(2n)). The materials for the light emitting layer EML have at least the relationship of T1_BD>T1_BH1>T1_BH2 in triplet energy levels.

The dopant BD commonly contained in each layer (EMA1, EMA2, EMA3, . . . ) of the light emitting layer EML can be a fluorescent dopant and can be a dopant capable of delayed fluorescence.

Unlike FIGS. 1 to 3 described above, when the light emitting layer is formed as a multi-light emitting layer, and the first layer adjacent to the first common layer CML1 contains a host having a low triplet energy level, triplet excitons can move to the first layer and concentrate at the interface contacting the first common layer, causing an increase in the excitons that are not used for light emission and are quenched, which can have a negative effect on both luminous efficacy and lifespan.

The light emitting device according to the embodiment of the present disclosure can include a light emitting layer EML having odd-numbered layers (EMA1, EMA3, . . . EMA(2n+1)) containing different first hosts BH1 and even-numbered layers (EMA2, . . . EMA(2n)) containing second hosts BH2, and can be formed in a single chamber.

Meanwhile, the light emitting device according to the embodiment of the present disclosure includes a light emitting layer EML that emits light with a wavelength of 430 nm to 495 nm, approximately blue.

A blue light emitting device has low visibility and low lifespan. Therefore, improving efficiency and lifespan of blue light emitting devices relative to light emitting devices of other colors is a major technical challenge. The light emitting device according to the embodiment of the present disclosure includes a plurality of blue light emitting layers, but the internal materials are different to separate the layers, thereby improving both luminous efficacy and lifespan.

However, the embodiment of the present disclosure is not limited thereto. Although a light emitting dopant emitting light with a different color is included, the multiple light emitting layers are divided into an odd number of layers, the odd-numbered layers contain a first host, and the even-numbered layers contain a second host having a lower triplet energy level than the first host, thereby separating the common layer adjacent to both interfaces of the light emitting layer and the layer of the light emitting layer that emits delayed fluorescence based on the TTF mechanism, preventing excitons from accumulating at both interfaces of the light emitting layers, and improving the lifespan.

In the light emitting device according to the embodiment of the present disclosure, the light emitting layer is divided into an odd number of layers, different first and second hosts are alternately disposed, and the dopant is commonly provided in each layer, so that the first and last layers of the light emitting layer include the first host and the dopant, and the layers having the first host and the dopant come into contact with the first common layer and the second common layer at the two interfaces of the light emitting layer EML.

The light emitting layer of the present disclosure can be formed in accordance with the following manufacturing method.

The host materials of the multiple light emitting layers of the light emitting device according to the embodiment of the present disclosure can be changed by controlling a deposition area in the same chamber.

Therefore, the light emitting device according to the embodiment of the present disclosure can be divided into multiple light emitting layers using a single chamber. For example, when odd layers are formed in the light emitting layer, the deposition gas injection area of the supply source of the first host BH1 face the substrate so as to selectively supply the first host, and when even layers are formed, the deposition gas injection area of the second host BH2 faces the substrate so as to selectively supply the second host BH2. For example, the injection areas of the first host BH1 and the second host BH2 do not overlap each other and the dopant BD overlaps both the injection areas of the first and second hosts BH1 and BH2, so that the hosts of the odd and even layers are different.

As a result, the light emitting device according to the embodiment of the present disclosure can include a light emitting layer formed using different hosts for the odd-numbered layers and the even-numbered layers using a single chamber. Therefore, the light emitting device according to the embodiment of the present disclosure is capable of solving the problems of reduced yield and additional process equipment that occur when disposing each chamber to form multiple layers of the light emitting layer using multiple chambers.

The light emitting device according to the embodiment of the present disclosure has a configuration in which the layer where the delayed fluorescence is concentrated by the TTF mechanism is disposed in the even layer within the odd-numbered emission layers, so that the excitons that are quenched in the light emitting layer are recycled, the light emitting efficiency is improved and lifespan degradation caused by exciton accumulation is prevented at the interface between the common layer and the light emitting layer.

Hereinafter, the effect of the light emitting device according to the present disclosure will be described with reference to experiments. In the following experiments, the first host BH1 has the triplet energy level of 2.1 eV, the second host BH2 has the triplet energy level of 1.8 eV and the dopant BD has the triplet energy level of 2.7 eV as shown in Table 1 as below. More specifically, in the following experiments, the first host BH1, the first second host BH2, the dopant BD, the first common layer CML1 and the second common layer have the triplet energy levels, HOMO energy level and LUMO energy levels as shown in Table 3 as below. For example, in the following experiments, the first host BH1 is used a compound including a pyrene and having the triplet energy level of 2.1 eV, and the second host BH2 is used a compound including an anthracene and having the triplet energy level of 1.8 eV. The dopant BD comprises the boron-based compound selected from one of the Formulae 1 to 9 mentioned above. The Formulae 1 to 9 similarly have a higher triplet energy levels than the triplet energy levels of the first host BH1 and the second host BH2. The hosts and the dopant can be replaced with different materials if they have a triplet level relationship and an energy bandgap characteristic at the odd and even layers in the light emitting layer as shown in FIG. 3.

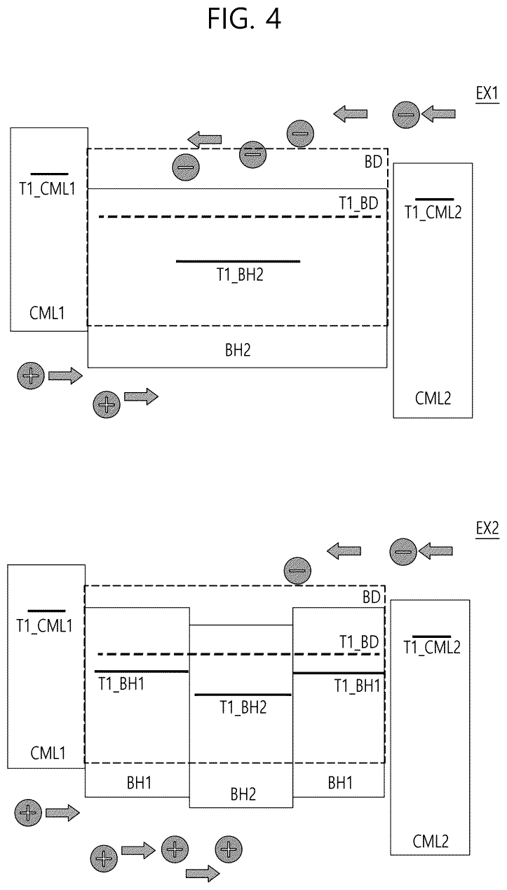

FIG. 4 illustrates light emitting layers of Experimental Examples 1 and 2.

As shown in FIG. 4, Experimental Example 1 EX1 has the same configuration as in the light emitting device of FIG. 1, except that the light emitting layer is formed as a single layer, and the second host BH2 and a blue light emitting dopant BD are contained in the single light emitting layer. Here, the total thickness of the light emitting layer EML of Experimental Example 1 EX1 is 180 Å.

Experimental Example 2 EX2 has the same configuration as in the light emitting device of FIG. 1. Accordingly, the first layer EMA1 contains the first host BH1 and the dopant BD, the second layer EMA2 contains the second host BH2 and the dopant BD, and the third layer EMA3 contains the first host BH1 and the dopant BD. The layer thicknesses of the first to third layers EMA1, EMA2, and EMA3 were each set to 60 Å.

The triplet energy levels of the first host BH1, second host BH2, and dopant BD used in the experiment are as shown in Table 1.

TABLE 1

| Item | BD | BH1 | BH2 |
|---|---|---|---|
| T1[eV] | 2.7 | 2.1 | 1.8 |

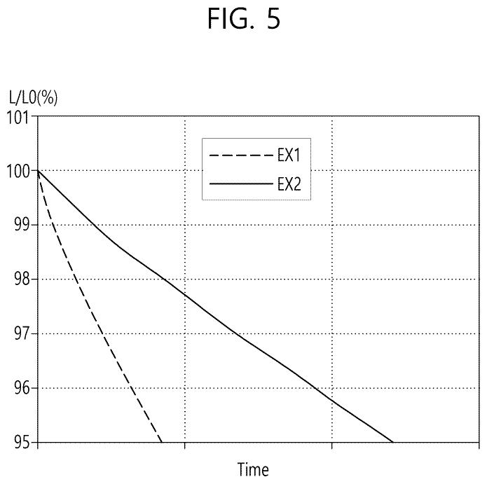

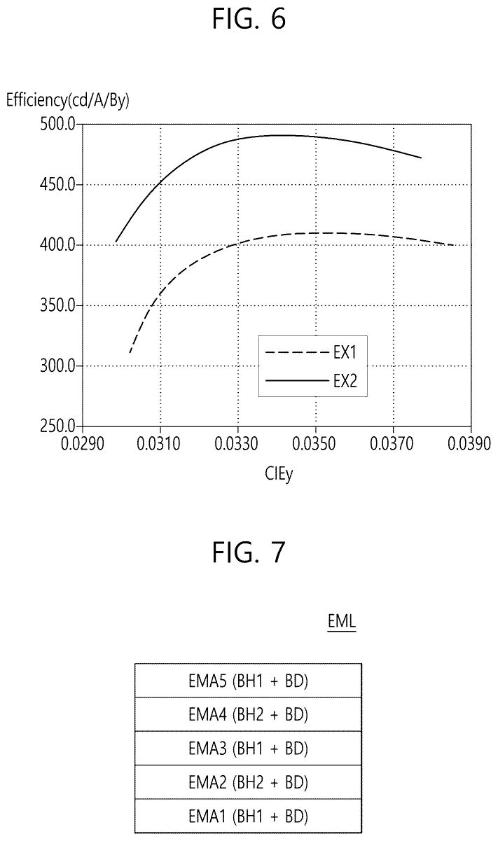

First, referring to FIGS. 5 and 6, the effects will be compared between Experimental Example 1 EX1 including a single light emitting layer containing a single host and Experimental Example 2 EX2 in which the odd and even layers of the light emitting layer EML contain different hosts.

FIG. 5 is a graph showing the 95-lifespan of light emitting devices according to Experimental Examples 1 and 2. FIG. 6 is a graph showing the luminance efficiency depending on the CIEy of light emitting devices according to Experimental Examples 1 and 2.

The 95-lifespan refers to the time until the luminance reaches 95% of the initial luminance.

As can be seen from FIG. 5, the lifespan of Experimental Example 2 EX2 containing the first host BH1 in the odd layers and the second host BH2 in the even layers is more than twice that of Experimental Example 1 EX1 containing a single host.

FIG. 6 shows the luminance efficiency of Experimental Examples 1 and 2 EX1 and EX2 at CIEy of 0.0290 to 0.0390, at which pure luminance of blue appears. The luminance efficiency of Experimental Example 2 EX2 is improved compared to the luminance efficiency of Experimental Example 1 EX1 in the entire range of the CIEy of 0.0290 to 0.0390. As can be seen from Table 2, Experimental Example 2 EX2 exhibits an increase to 112.6% in blue index (%) efficiency compared to Experimental Example 1 EX1.

The experiments showed that Experimental Example 2 EX2 including first and second layers, each containing a host and a single dopant, and including a third layer as the top layer exhibited improvement in both the lifespan and the pure color efficiency compared to Experimental Example 1 EX1 including the light emitting layer containing a single host material.

TABLE 2

| | | Driving | Blue | |
|---|---|---|---|---|
| | | voltage | Index | Lifespan |
| Item | Light emitting layer | (V) | (%) | (%) |
| EX1 | (BH2 + BD) | Vr | 100 | 100 |
| EX2 | (BH1 + BD)/(BH2 + BD)/ | Vr-0.150 | 112.6 | 363 |
| | (BH1 + BD) | | | |

In addition, the results of Table 2 showed that the driving voltage is reduced by 0.150 V in Experimental Example 2 EX2 compared to Experimental Example 1 EX1.

As can be seen from Table 2 and FIGS. 5 and 6, the driving voltage is significantly reduced and the blue index efficiency is improved in Experimental Example 2 EX2 compared to Experimental Example 1 EX1. In addition, it can be seen that the lifespan is improved by more than three times in Experimental Example 2 EX2 compared to Experimental Example 1 EX1.

Meanwhile, the multilayer structure of the light emitting layer in the light emitting device of the present disclosure is divided into an odd number of layers and is not limited to the three-layer structure disclosed in FIGS. 2 and 3.

FIG. 7 is a cross-sectional view illustrating an example in which the light emitting layer according to another embodiment of the present disclosure has a five-layer structure.

Referring to FIG. 7, the light emitting layer EML can also be divided into five layers.

The first, third, and fifth layers EMA1, EMA3, and EMA5 contain a first host BH1 and a dopant BD, and the second and fourth layers EMA2 and EMA4 contain a second host BH2 and a dopant BD.

Due to the difference between triplet energy level T1_BH1 of the first host BH1 of the first, third, and fifth layers EMA1, EMA3, and EMA5, and the triplet energy level T1_BH2 of the second host BH2 of the second and fourth layers EMA2 and EMA4, the delayed fluorescence by the TTF mechanism in the second and fourth layers EMA2 and EMA4 is more dominant than that in the first, third, and fifth layers EMA1, EMA3, and EMA5.

Although the light emitting layer EML of FIG. 7 is divided into five layers, the effects of reduced driving voltage, improved efficiency, and improved lifespan can be obtained like the case where the light emitting layer EML described above is divided into three layers.

Meanwhile, the example in which a single light emitting stack is provided between the first electrode AND and the second electrode CAT has been described above.

Hereinafter, for example, in a light emitting device including multiple stacks, the light emitting layer of at least one stack can be configured as multiple layers as described with reference to FIGS. 1 to 4 to obtain the effects of improved lifespan and efficiency. Hereinafter, a light emitting device according to another embodiment will be described.

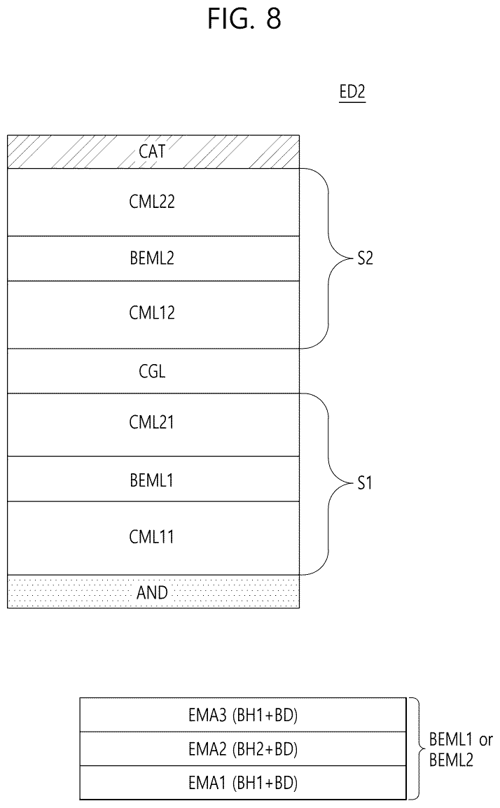

FIG. 8 is a cross-sectional view illustrating a light emitting device according to another embodiment of the present disclosure.

As shown in FIG. 8, the light emitting device ED2 according to another embodiment of the present disclosure includes a first stack S1, a charge generation layer CGL, and a second stack S2 sequentially disposed between the first electrode AND and the second electrode CAT facing each other. The first stack S1 and the second stack S2 each include a first common layer CML11 and CML12, a blue light emitting layer BEML1 and BEML2, and a second common layer CML21 and CML22. The first common layer CML11 and CML12 can comprise hole transport property material and the second common layer CML21 and CML22 can comprise electron transport material.

The first stack S1 and the second stack S2 each include a first common layer CML11 and CML12 functioning to transport holes, a blue light emitting layer BEML1 and BEML2, and a second common layer CML21 and CML22 functioning to transport electrons.

The first common layer CML11 and CML12 can include a hole injection layer, a hole transport layer, an electron blocking layer, and the like.

The second common layer CML21 and CML22 can include a hole blocking layer, an electron transport layer, an electron injection layer, and the like.

In the structure having multiple stacks, the hole injection layer can be provided in the first stack S1 contacting the first electrode AND, and the electron injection layer can be provided in the second stack S2 contacting the second electrode CAT.

The charge generation layer CGL can be formed by laminating a p-type charge generation layer PCGL and an n-type charge generation layer NCGL.

Here, the first stack S1 includes a first blue light emitting layer BEML1, and the second stack S2 includes a second blue light emitting layer BEML2.

At least one of the first and second blue light emitting layers BEML1 and BEML2 can have a multilayer structure with an odd number of layers, for example, include first to third layers EMA1, EMA2, and EMA3 as described above with respect to FIGS. 1 to 4. The first to third layers EMA1, EMA2, and EMA3 commonly include a dopant BD. The first layer EMA1 and the third layer EMA3, which are odd-numbered layers, contain a first host BH1, and the second layer EMA2 contains a second host BH2 having a lower triplet energy level than the first host.

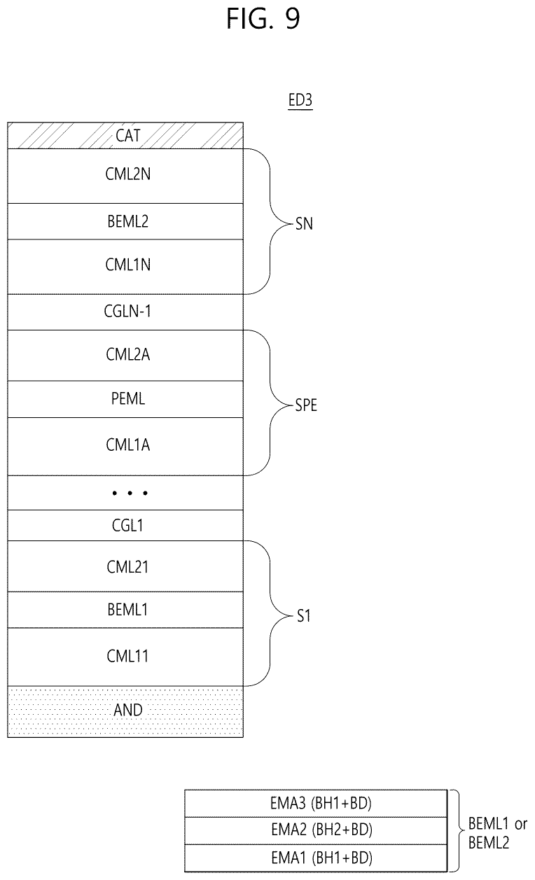

FIG. 9 is a cross-sectional view illustrating a light emitting device according to another embodiment of the present disclosure.

As shown in FIG. 9, the light emitting device ED3 according to another embodiment of the present disclosure includes three or more stacks between a first electrode AND and a second electrode CAT.

A charge generation layer CGL1 to CGLN-1 can be provided between the three or more stacks S1, SPE, and SN. The charge generation layer CGL1 to CGLN-1 can include a laminate of an n-type charge generation layer NCGL and a p-type charge generation layer PCGL.

Two stacks S1 and SN among the three or more stacks provided between the first and second electrodes AND and CAT include blue light emitting layers BEML1 and BEML2.

The illustrated example is a case in which the first stack S1 and the Nth stack SN have blue light emitting layers BEML1 and BEML2, but the embodiment is not limited thereto.

Between the first stack S1 and the Nth stack SN, one or more phosphorescent light emitting stacks SPE including a phosphorescent light emitting layer PEML can be included. In some cases, the phosphorescent light emitting layer PEML can be a laminate of phosphorescent light emitting layers that emit light with different colors.

In each stack S1, SPE, or SN, a first common layer CML11, CML1A, or CML1N functioning to transport holes can be provided at the bottom of each light emitting layer BEML1, PEML, BEML2, and a second common layer CML21, CML2A, or CML2N functioning to transport electrons can be provided at the top of each light emitting layer BEML1, PEML, BEML2.

For example, the first stack S1 includes a first blue light emitting layer BEML1 and the Nth stack SN includes a second blue light emitting layer BEML2.

At least one of the first and second blue light emitting layers BEML1 and BEML2 can have a multilayer structure with an odd number of layers, for example, include first to third layers EMA1, EMA2, and EMA3 as described above with respect to FIGS. 1 to 4. The first to third layers EMA1, EMA2, and EMA3 commonly include a dopant BD. The first layer EMA1 and the third layer EMA3, which are odd-numbered layers, include a first host BH1, and the second layer EMA2 includes a second host BH2 having a lower triplet energy level than the first host.

Meanwhile, an example in which a different structure is applied to the first blue light emitting layer BEML1 adjacent to the first electrode AND and the second blue light emitting layer BEML2 adjacent to the second electrode CAT for the first and second blue light emitting layers BEML1 and BEML2 having the multilayer structure of FIG. 8 or 9 and the significance thereof will be described.

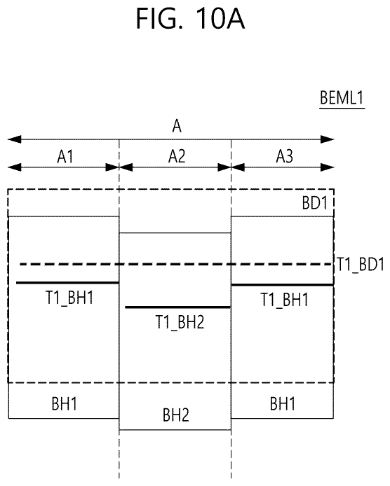

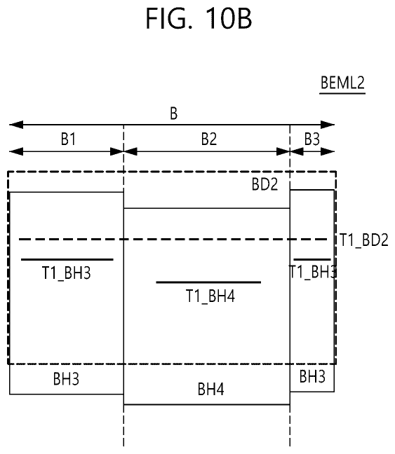

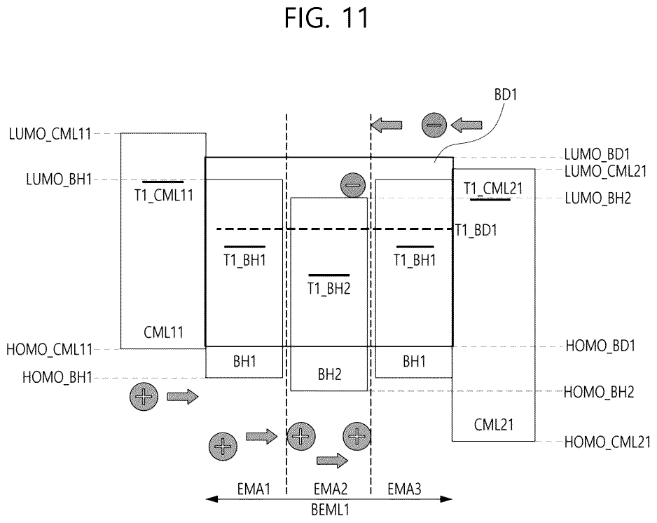

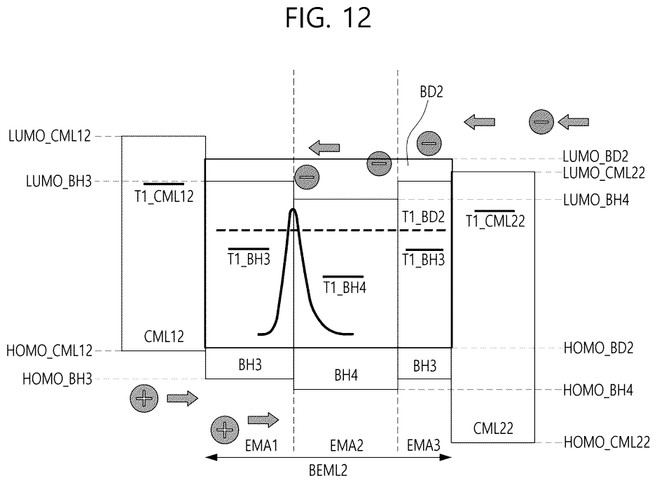

FIGS. 10A and 10B illustrate layered structures of the first blue light emitting layer and the second blue light emitting layer of FIG. 8 or 9, respectively, according to one embodiment of the present disclosure. FIG. 11 is an energy band diagram of the first blue light emitting stack of FIG. 8 or FIG. 9. FIG. 12 is an energy band diagram of the second blue light emitting stack of FIG. 8 or 9.

As shown in FIG. 10A, the first blue light emitting layer BEML1 adjacent to the first electrode AND can have thicknesses A1, A2, A3 of multiple layers that are the same or similar (A1≅A2≅A3). The example illustrated in FIG. 10A is that the first blue light emitting layer BEML1 is formed as a three-layer structure, the first layer EMA1 and the third layer EMA3 contain the first blue host BH1 having high triplet energy levels T1_BH1 and the first blue dopant BD1, respectively, and the second layer EMA2 contains the second blue host BH2 having relatively low triplet energy levels T1_BH2 and the first blue dopant BD1. In an example, the thicknesses A1, A2, A3 can be same or similar to each other, and each of them can range from 2 nanometers to 15 nanometers (20˜150 Å), from 3 nanometers to 10 nanometers, from 4 nanometers to 9 nanometers, or from 5 nanometers to 8 nanometers. In another example, the thicknesses A1, A2, A3 can be same as or different from each other, and each can independently range from 2 nanometers to 15 nanometers, from 3 nanometers to 10 nanometers, from 4 nanometers to 9 nanometers, or from 5 nanometers to 8 nanometers. For example, the thickness A1 can be 4 nanometers or more, 5 nanometers or more, 6 nanometers or more, 7 nanometers or more, or 8 nanometers or more; the thickness A2 can be 6 nanometers or more, 7 nanometers or more, or 8 nanometers or more; the thickness A3 can be 8 nanometers or less, 7 nanometers or less, 5 nanometers or less, or 3 nanometers or less.

As shown in FIG. 10B, the second blue light emitting layer BEML2 adjacent to the second electrode CAT can have different thicknesses B1, B2, B3 of the multiple layers. The second layer EMA2, which is an even layer in the second blue light emitting layer BEML2, can be the thickest, and the third layer EMA3 adjacent to the second electrode CAT can be the thinnest. For example, the second thickness B2 of the second layer EMA2 can be greater than the first thickness B1 of the first layer EMA1, and the third thickness B3 of the third layer EMA3 can be less than the first thickness B1. In the example illustrated in FIG. 10B, the second blue light emitting layer BEML2 has a three-layer structure, and the first layer EMA1 and the third layer EMA3 contain a third blue host BH3 having a high triplet energy level T1_BH3 and a second blue dopant BD2, respectively, and the second layer EMA2 contain a fourth blue host BH4 having a relatively low triplet energy level T1_BH4 and a second blue dopant BD2. For example, the thickness B1 can range from 3 nanometers to 10 nanometers, the thickness B2 can range from 5 nanometers to 12 nanometers, the thickness B3 can range from 2 nanometers to 8 nanometers.

Here, the total thickness A of the multilayer structure of the first blue light emitting layer BEML1 and the total thickness B of the multilayer structure of the second blue light emitting layer BEML2 can be equal to or different from each other. For example, the total thickness A and the total thickness B can each independently range from 6 nanometers to 50 nanometers, from 8 nanometers to 40 nanometers, from 10 nanometers to 30 nanometers, or from 12 nanometers to 24 nanometers.

The first blue host BH1 of the first blue light emitting layer BEML1 can be the same as the third blue host BH3 of the second blue light emitting layer BEML2 and the second blue host BH2 of the first blue light emitting layer BEML1 can be the same as the fourth blue host BH4 of the second blue light emitting layer BEML2.

The first blue dopant BD1 of the first blue light emitting layer BEML1 can be the same as the second blue dopant BD2 of the second blue light emitting layer BEML2, but the embodiments of the present disclosure are not limited thereto.

When the triplet energy levels T1_BD1, T1_BH1, T1_BH2 in the first blue light emitting layer BEML1 decrease in the order of the first blue dopant, the first blue host, and the second blue host (T1_BD1>T1_BH1>T1_BH2), and the triplet energy levels T1_BD2, T1_BH3, T1_BH4 in the second blue light emitting layer BEML2 decrease in the order of the second blue dopant, the third blue host, and the fourth blue host (T1_BD2>T1_BH3>T1_BH4), the materials for the first blue light emitting layer and the second blue light emitting layer can be changed.

Here, the thickness B3 of the third layer EMA3 of the last layer of the second blue light emitting layer BEML2 contacting the second common layer CML22 of the second blue light emitting stack can be less than the thickness A3 of the third layer EMA3 of the last layer of the first blue light emitting layer BEML1 contacting the second common layer CML21 of the first blue light emitting stack (A3>B3).

In the second blue light emitting stack, the thickness B3 of the third layer EMA3 of the second blue light emitting layer BEML2 contacting the second common layer CML22 can be less than the thickness B2 of the second layer EMA2 contacting the third layer EMA3 (B2>B3).

In the second blue light emitting stack, the thickness B3 of the third layer EMA3 of the second blue light emitting layer BEML2 contacting the second common layer CML22 can be less than the thickness B1 of the first layer EMA1 of the second blue light emitting layer BEML2 contacting the first common layer CML12 (B1>B3). In an example, the thickness B1 of the first layer EMA1 can be 1.5 times or more, 1.7 times or more, 1.8 times or more, for example, twice or more, the thickness B3 of the third layer EMA3. Therefore, while keeping the total thickness of the light emitting layer unchanged, the recombination region can be expanded, and the region where the exciton generation region and the TTF mechanism occur can be secured, so that the lifespan can be improved and the efficiency can be increased.

Here, the first blue light emitting layer BEML1 and the second blue light emitting layer BEML2 have a multilayer structure with a thickness difference because the adjacent electrodes are different, the transfer speeds of holes and electrons are different and thus the formed recombination regions are different.

The first blue light emitting layer BEML1 of the first blue light emitting stack contacting the first electrode AND has a short distance from the first electrode AND, so the amount of holes injected is abundant. However, the vertical distance from the second electrode CAT to the first blue light emitting layer BEML1 is relatively longer than the vertical distance from the first electrode AND to the first blue light emitting layer BEML1, an electron movement distance is longer than a hole movement distance, and the supply speed of the electrons to the first blue light emitting layer BEML1 is slow. As shown in FIGS. 8 and 9, the first blue light emitting stack can receive electrons through the charge generation layer of the adjacent light emitting stack, particularly the n-type charge generation layer, but the electron transfer speed can be slower than that of the second blue light emitting layer BEML2 which is relatively adjacent to the second electrode CAT. In this case, as shown in FIGS. 11 and 12, since there is a difference in the transport speed of holes and electrons between the first blue light emitting layer BEML1 and the second blue light emitting layer BEML2, the recombination region can occur in a wider region in the first blue light emitting layer BEML1 than in the second blue light emitting layer BEML2. Even within the first blue light emitting layer BEML1, the intensity of recombination of holes and electrons can be the highest between the first layer EMA1 and the second layer EMA2. However, when the thickness of the first layer EMA1 in the first blue light emitting layer BEML1 is increased, the location where the recombination region occurs moves to the center of the first blue light emitting layer BEML1, and in this case, the TTF efficiency in the second layer EMA2 can decrease. Therefore, as shown in FIG. 10A and FIG. 11, the thicknesses of each layer EMA1, EMA2, and EMA3 of the first blue light emitting layer BEML1 can be equal or similar.

Meanwhile, as shown in FIGS. 10B and 12, the second blue light emitting layer BEML2 adjacent to the second electrode CAT has a high electron injection speed. Therefore, when each layer of the second blue light emitting layer BEML2 has the same thickness, a recombination region can be formed in a local region adjacent to the first common layer CML12 functioning to transport holes. Accordingly, the recombination region is formed closer to the center of the second blue light emitting layer BEML2, the interface between the first layer EMA1 and the second layer EMA2 having a large distribution of recombination regions is disposed closer to the center of the second blue light emitting layer BEML2, and the thickness B1 of the first layer EMA1 of the second blue light emitting layer BEML2 is larger than the thickness A1 of the first layer EMA1 of the first blue light emitting layer BEML1. In addition, the first layer EMA1 and the second layer EMA2 of the second blue light emitting layer BEML2 undergo energy transfer from the third blue host BH3 to the fourth blue host BH4 due to the difference in triplet energy levels, and thus delayed fluorescence occurs in the second layer EMA2 by the TTF mechanism. Therefore, in order to maximize the TTF efficiency and thus the luminous efficacy and lifespan, the thickness B2 of the second layer EMA2 can be set as thick as possible in the second blue light emitting layer BEML2 (B2>B1, B2>B3).

In the second blue light emitting layer BEML2, the third layer EMA3, which is the last layer wherein it is difficult for a recombination region to occur due to the fast electron transfer speed, is thin, and the first and second layers, where the recombination region distribution is large, are relatively thick. Here, in terms of the occurrence of a recombination region, the thickness B1 of the first layer EMA1 of the second blue light emitting layer BEML2 is at least a predetermined level so as to secure performance, the first layer EMA1 of the second blue light emitting layer BEML2 has a greater thickness sensitivity than the first thickness A1 of the first blue light emitting layer BEML1. Therefore, the thickness B1 of the first layer EMA1 of the second blue light emitting layer BEML2 can be greater than or equal to the first thickness A1 of the first blue light emitting layer BEML1 (B1≥A1).

Meanwhile, the content of the first blue dopant BD1 of each layer in the first blue light emitting layer BEML1 is the same.

The content of the second blue dopant BD2 of each layer in the second blue light emitting layer BEML2 is the same.

Therefore, the recombination region of each layer of the first blue light emitting layer BEML1 and each layer of the second blue light emitting layer BEML2 can be adjusted by the thickness and the material of the host.

Referring to FIG. 11, in the first stack S1 contacting the first electrode AND, the first common layer CML11 includes a hole transport layer contacting the first layer EMA1 of the first blue light emitting layer BEML1 as a hole transport common layer. The second common layer CML21 includes an electron transport layer contacting the last layer EMA3 of the first blue light emitting layer BEML1 as an electron transport common layer. Referring to FIG. 8 or FIG. 9, the second common layer CML21 can contact an n-type charge generation layer of the charge generation layer.

The LUMO energy level LUMO_BD1 of the first blue dopant BD1 is higher than the LUMO energy level LUMO_BH1, LUMO_BH2 of each of the first and second hosts (LUMO_BD1>LUMO_BH1, LUMO_BD1>LUMO_BH2). Electrons injected from the second common layer CML21 through the LUMO energy level LUMO_BD1 of the first blue dopant BD1 are easily injected into the LUMO energy levels LUMO_BH1, LUMO_BH2 of the first and second hosts BH1 and BH2 in each layer of the light emitting layer.

Either of the triplet energy level T1_CML11 of the first common layer CML11 and the triplet energy level T1_CML21 of the second common layer CML21 is greater than the triplet energy level T1_BD1 of the first blue dopant BD1. The first common layer CML11 has a LUMO energy level LUMO_CML11 that is higher than the LUMO energy level LUMO_BD1 of the first blue dopant BD1 (LUMO_CML11>LUMO_BD1) and a HOMO energy level HOMO_CML11 that is lower than the HOMO energy level HOMO_BD1 of the first blue dopant BD1 (HOMO_CML11<HOMO_BD1). The second common layer CML21 can have a LUMO energy level LUMO_CML21 that is lower than the LUMO energy level LUMO_BD1 of the first blue dopant BD1 and a HOMO energy level HOMO_CML21 that is lower than the HOMO energy level HOMO_BD1 of the first blue dopant BD1.

The HOMO energy level HOMO_BD1 of the first blue dopant BD1 can be higher than the HOMO energy level HOMO_BH1, HOMO_BH2 of each of the first and second hosts (HOMO_BD1>HOMO_BH1, HOMO_BD1>HOMO_BH2).

Referring to FIG. 12, in the second stack S2 or the Nth stack SN contacting the second electrode CAT, the first common layer CML12 includes a hole transport layer contacting the first layer EMA1 of the second blue light emitting layer BEML2 as a hole transport common layer. The second common layer CML22 includes an electron transport layer contacting the last layer EMA3 of the second blue light emitting layer BEML2 as an electron transport common layer. The second common layer CML22 can contact the electron injection layer or directly contact the second electrode CAT.

The LUMO energy level LUMO_BD2 of the second blue dopant BD2 is higher than the LUMO energy levels LUMO_BH3, LUMO_BH4 of each of the third and fourth hosts (LUMO_BD2>LUMO_BH3, LUMO_BD2>LUMO_BH4). Electrons injected from the second common layer CML22 through the LUMO energy level LUMO_BD2 of the second blue dopant BD2 can be easily injected into the LUMO energy levels LUMO_BH3 and LUMO_BH4 of the third and fourth hosts BH3 and BH4 in each layer of the light emitting layer.

Either of the triplet energy level T1_CML12 of the first common layer CML12 and the triplet energy level T1_CML22 of the second common layer CML22 is greater than the triplet energy level T1_BD2 of the second blue dopant BD2. The first common layer CML12 with hole transport property has a LUMO energy level LUMO_CML12 higher than the LUMO energy level LUMO_BD2 of the second blue dopant BD2 (LUMO_CML12>LUMO_BD2) and a HOMO energy level HOMO_CML12 lower than the HOMO energy level HOMO_BD2 of the second blue dopant BD2 (HOMO_CML12<HOMO_BD2). The second common layer CML22 can have a LUMO energy level LUMO_CML22 lower than the LUMO energy level LUMO_BD2 of the second blue dopant BD2 and a HOMO energy level HOMO_CML22 that is lower than the HOMO energy level HOMO_BD2 of the second blue dopant BD2.

The HOMO energy level HOMO_BD2 of the second blue dopant BD2 can be higher than the HOMO energy levels HOMO_BH3 and HOMO_BH4 of the third and fourth hosts (HOMO_BD2>HOMO_BH3, HOMO_BD2>HOMO_BH4).

Meanwhile, the HOMO energy level and LUMO energy level described above have negative values based on the vacuum level, which means that, in comparison of one material with another material, when the HOMO energy level or the LUMO energy level of one material is higher than that of the other material, the absolute value thereof is smaller.

Hereinafter, based on the light emitting device of the structure of FIG. 8, the first blue light emitting layer BEML1 and the second blue light emitting layer BEML2 have the same multilayer structure, the thickness of the second layer, which is the even layer, is set to the largest, and the significance of the thickness difference of the odd layers is described. The first blue light emitting layer BEML1 and the second blue light emitting layer BEML2 each include three layers. In the first blue light emitting layer BEML1, the first layer EMA1 and the third layer EMA3 contain a first blue host BH1 having high triplet energy levels and a first blue dopant BD1, and the second layer EMA2 contain a second blue host BH2 having relatively low triplet energy levels and the first blue dopant BD1. The triplet energy levels of the first blue host BH1, the second blue host BH2, and the first blue dopant BD1 have the following relationship: T1_BD1>T1_BH1>T1_BH2.

In the second blue light emitting layer BEML2, the first layer EMA1 and the third layer EMA3 contain a third blue host BH3 having high triplet energy levels and a second blue dopant BD2, and the second layer EMA2 contains a fourth blue host BH4 having lower triplet energy levels and a second blue dopant BD2. The triplet energy levels of the third blue host BH3, the fourth blue host BH4, and the second blue dopant BD2 have the following relationship: T1_BD2>T1_BH3>T1_BH4.

In the following experiments, the first blue dopant BD1 is the same material as the second blue dopant BD2, the first blue host BH1 and the third blue host BH3 are the same, and the second blue host BH2 and the fourth blue host BH4 are the same.

Experimental Examples 4, 5, and 6 EX4, EX5, and EX6 have differences in thickness of the light emitting layer. In each blue light emitting layer, the first layer EMA1 has a thickness of 50 Å and the second layer EMA2 has a thickness of 80 Å. In Experimental Example 4 EX4, the thickness of the third layer EMA3 is 30 Å, in Experimental Example 5 EX5, the thickness of the third layer EMA3 is 50 Å, and in Experimental Example 6 EX6, the thickness of the third layer EMA3 is 70 Å.

In Experimental Example 7 EX7, the thickness of the first layer EMA1 in each blue light emitting layer is 70 Å, the thickness of the second layer EMA2 is 80 Å, and the thickness of the third layer EMA3 is 30Λ.

In the following experiments, the LUMO energy level, HOMO energy level, and triplet energy level T1 of each material are shown in Table 3.

TABLE 3

| | BD1, | BH1, | BH2, | CML11, | CML21, |
|---|---|---|---|---|---|
| | BD2 | BH3 | BH4 | CML12 | CML22 |
| LUMO[eV] | −2.80 | −3.06 | −3.11 | −2.61 | −3.04 |
| HOMO[eV] | −5.60 | −6.11 | −6.12 | −5.70 | −6.54 |
| T1[eV] | 2.7 | 2.1 | 1.8 | 2.9 | 2.7 |

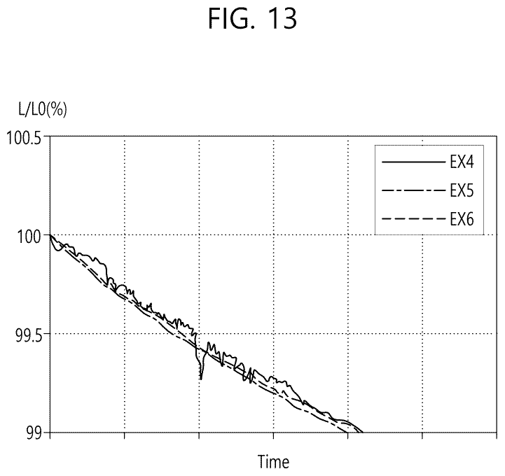

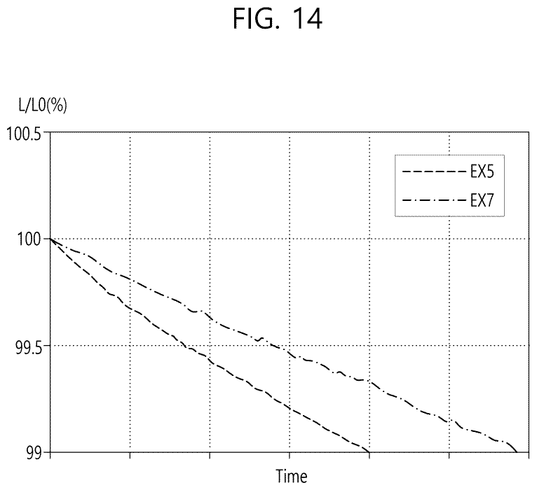

FIG. 13 is a graph showing comparison in lifespan between Experimental Examples 4, 5, and 6. FIG. 14 is a graph showing comparison in lifespan between Experimental Examples 5 and 7.

TABLE 4

| | | Driving | Blue | |
|---|---|---|---|---|
| | EMA1/EMA2/EMA3 | voltage | index | Lifespan |
| | [Å] | (V) | (%) | (%) |
| EX4 | 50/80/30 | V1 | 100 | 100 |
| EX5 | 50/80/50 | V1 + 0.1 V | 101.0 | 100 |
| EX6 | 50/80/70 | V1 + 0.2 V | 100.3 | 100 |
| EX7 | 70/80/30 | V1 + 0.06 V | 103.5 | 139 |

As can be seen from Table 4 and FIG. 13, Experimental Examples 4, 5, and 6 EX4, EX5, EX6 have a configuration in which the first layer EMA1 and the second layer EMA2 have the same thickness and the third layer EMA3 has a different thickness, and thus there is almost no difference in blue index efficiency or lifespan. This is because the driving voltage has increased and the thickness of the organic material in the light emitting device has increased. These results show that the increase in the thickness of the third layer, which is the last layer in the multilayered light emitting layer, is not a factor that causes changes in lifespan or efficiency.

From Table 4 and FIG. 14, Experimental Example 5 EX5 in which the thicknesses of the first layer EMA1 and the third layer EMA3 are the same, and Experimental Example 7 EX7 in which the thickness of the first layer EMA1 is greater than that of the third layer EMA3 such that there is a difference in thickness between the first layer EMA1 and the third layer EMA3 will be described. In Experimental Example 5 EX5, the thickness of the first layer EMA1 and the third layer EMA3 are set to 50 Å, respectively, and in Experimental Example 7 EX7, the thickness of the first layer EMA1 is set to 70 Å and the thickness of the third layer EMA3 is set to 30 Å, so that the total thickness of the blue light emitting layer of Experimental Example 5 EX5 and Experimental Example 7 EX7 are set to be the same.

Compared to Experimental Example 5 EX5, Experimental Example 7 EX7 has reduced driving voltage, increased blue index efficiency, and improved lifespan.

In other words, when the thickness of the first layer contacting the common layer functioning to transport holes for the light emitting layer is increased between odd-numbered layers, the recombination region can be expanded, and the region where the exciton generation region and the TTF mechanism occur can be secured, so that the lifespan can be improved and the efficiency can be increased.

In the following experiments, the significance of the thickness difference in the multilayer structure of the second blue light emitting layer BEML2 will be described through Experimental Example 8 EX8 in which the first blue light emitting layer BEML1 and the second blue light emitting layer BEML2 are the same, and the structure in which there is a difference in the thickness between the first blue light emitting layer BEML1 and the second blue light emitting layer BEML2.

Based on the light emitting device of the structure of FIG. 8, Experimental Example 8 EX8 has the same three-layer structure as the first blue light emitting layer BEML1 and the second blue light emitting layer BEML2, and the thicknesses of the first layer, the second layer, and the third layer are 50 Å, 80 Å, and 50 Å, respectively. In Experimental Example 9 EX9, the thicknesses of the first layer, the second layer, and the third layer of the first blue light emitting layer BEML1 are 50 Å, 80 Å, and 50 Å, respectively, and the thicknesses of the first layer, the second layer, and the third layer of the second blue light emitting layer BEML2 are 70 Å, 80 Å, and 30 Å, respectively.

The first blue light emitting layer BEML1 and the second blue light emitting layer BEML2 each include three layers. In the first blue light emitting layer BEML1, the first layer EMA1 and the third layer EMA3 contain a first blue host BH1 having a high triplet energy level and a first blue dopant BD1, and the second layer EMA2 contains a second blue host BH2 having a relatively low triplet energy level and a first blue dopant BD1. The triplet energy levels of the first blue host BH1, the second blue host BH2, and the first blue dopant BD1 have the following relationship: T1_BD1>T1_BH1>T1_BH2.

The first blue dopant BD1 is formed of the same material as the second blue dopant BD2, the first blue host BH1 and the third blue host BH3 are formed of the same material, and the second blue host BH2 and the fourth blue host BH4 are formed of the same material.

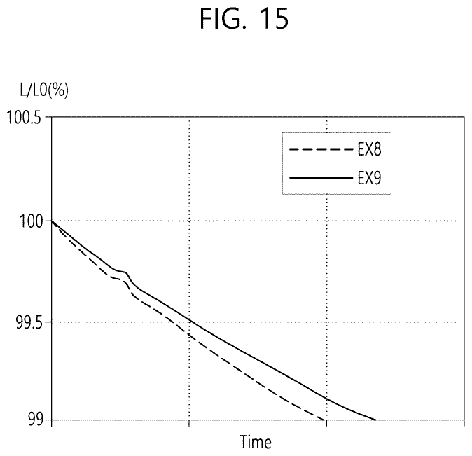

FIG. 15 is a graph showing comparison in lifespan between Experimental Examples 8 and 9.

TABLE 5

| | BEML1 | BEML2 | Driving | Blue | Life- |
|---|---|---|---|---|---|
| | (EMA1/EMA2/ | (EMA1/EMA2/ | Voltage | In- | span |
| Item | EMA3)[Å] | EMA3) [Å] | (V) | dex(%) | (%) |
| EX8 | 50/80/50 | 50/80/50 | V2 | 100 | 100 |
| EX9 | 50/80/50 | 70/80/30 | V2-0.05 | 103.3 | 110 |

As can be seen from Table 5 and FIG. 15, when the thickness of the first layer EMA1 of the second blue light emitting layer BEML2 is greater than that of the third layer EMA3, as in Experimental Example 9 EX9, the driving voltage is reduced, the blue index efficiency is increased, and the lifespan is also improved.

This means that, when the thickness of the first layer EMA1 is greater than that of the third layer EMA3 such that the recombination region is closer to the center in consideration of the fast electron transfer speed in the second blue light emitting layer BEML2, the degree of quenching of excitons can be reduced by adjusting the recombination region, the driving voltage can be reduced while maintaining the same thickness of the blue light emitting layer, and the efficiency and lifespan can be improved.

Hereinafter, an example of a light emitting display device using the light emitting device according to an embodiment of the present disclosure will be described.

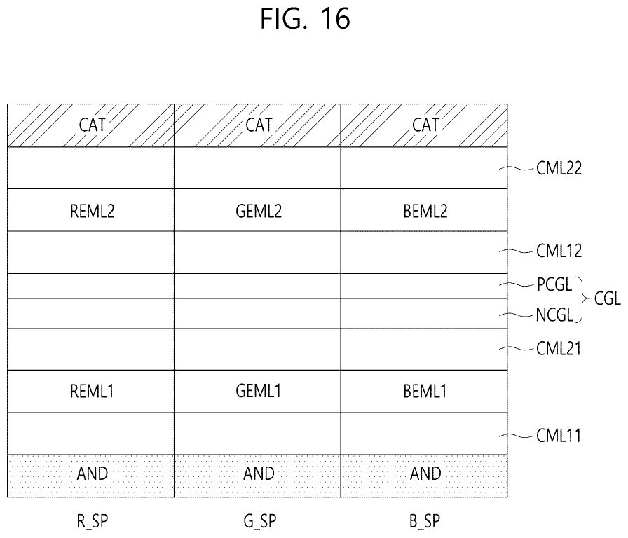

FIG. 16 is a cross-sectional view illustrating light emitting devices of a red subpixel, a green subpixel, and a blue subpixel in the light emitting display device according to one embodiment of the present disclosure.

As shown in FIG. 16, the light emitting display device according to one embodiment of the present disclosure can include a first electrode AND and a second electrode CAT facing each of a red subpixel R_SP, a green subpixel G_SP, and a blue subpixel B_SP, a plurality of stacks between the first electrode AND and the second electrode CAT, and light emitting layers that emit light with the same color overlapping each other in the plurality of stacks. For example, the red subpixel R_SP can have red light emitting layers REML1 and REML2 in separate stacks with a charge generation layer CGL therebetween, the green subpixel G_SP can have green light emitting layers GEML1 and GEML2 in separate stacks with a charge generation layer CGL therebetween, and the blue subpixel B_SP can have blue light emitting layers BEML1 and BEML2 in separate stacks with a charge generation layer CGL therebetween.

Here, a first common layer CML11 related to hole injection and hole transport is provided between the first electrode AND and the first red light emitting layer REML1, the first green light emitting layer GEML1, and the first blue light emitting layer BEML1, and a second common layer CML21 related to electron transport is provided between the first red light emitting layer REML1, the first green light emitting layer GEML1, and the first blue light emitting layer BEML1 and the charge generation layer CGL.

The charge generation layer CGL can be provided by laminating an n-type charge generation layer NCGL and a p-type charge generation layer PCGL.

In addition, a third common layer CML12 related to hole injection and hole transport can be provided between the charge generation layer CGL and the second red light emitting layer REML2, the second green light emitting layer GEML2, and the second blue light emitting layer BEML2, and a fourth common layer CML22 including an electron transport layer and an electron injection layer can be provided between the second red light emitting layer REML2, the second green light emitting layer GEML2, and the second blue light emitting layer BEML2 and the second electrode CAT.

The first common layer CML11 and the third common layer CML12 related to hole injection and transport can include at least one of a hole injection layer, a hole transport layer, and an electron blocking layer, and the second common layer CML21 and the fourth common layer CML22 related to electron transport and injection can include at least one of a hole blocking layer, an electron transport layer, and an electron injection layer.

Here, at least the first and second blue light emitting layers BEML1 and BEML2 provided at the blue subpixel B_SP are divided into an odd number of layers as described above, and each layer is provided with the same dopant, but the odd-numbered layer contacting the common layer can contain the first host BH1 or the third host BH3 having a large triplet energy level, and the even-numbered layer can contain the second host BH2 or the fourth host BH4 having a lower triplet energy level.

As a result, the light emitting display device according to the embodiment of the present disclosure can have the effects of improved lifespan and efficiency, and reduced driving voltage.

In addition, the light emitting device and the light emitting display device including the same according to the embodiment of the present disclosure include odd-numbered layers and even-numbered layers containing hosts with different properties. Among them, delayed fluorescence by the TTF mechanism is induced in the even-numbered layers, and the layer in which the TTF mechanism is caused by energy transfer is disposed as the even-numbered layer within the light emitting layer, is separated from both interfaces of the light emitting layer, so that the reduction in lifespan caused by exciton accumulation at the interface between the light emitting layer and the common layer can be solved.

In addition, the light emitting device and the light emitting display device including the same according to the embodiment of the present disclosure include the light emitting layer so that layers having different hosts are disposed alternately, and the number of light emitting layers is odd so that the hosts of the first layer and the last layer of the light emitting layer are the same. In addition, the odd-numbered layers of the light emitting layer contain a host having a high triplet energy level, and the even-numbered layers of the light emitting layer contain a host having a low triplet energy level. As a result, the delayed fluorescence efficiency by the TTF mechanism is increased in the inner even layer of the light emitting layer, which is located inside the first and last layers located on both interfaces of the light emitting layer and does not come into contact with both interfaces of the light emitting layer, thereby increasing the light emitting efficiency, and improving the efficiency of the light emitting device and the efficiency of the light emitting display device.

In addition, the light emitting device and the light emitting display device including the same according to the embodiment of the present disclosure can effectively improve the lifespan by reducing the quenching ratio of excitons generated in the light emitting layer and increasing the ratio used for direct light emission or delayed light emission.

In addition, the light emitting device and the light emitting display device including the same according to the embodiment of the present disclosure can prevent an increase in driving voltage and improve the lifespan by adjusting the thickness of the first and last layers, especially when forming the blue light emitting layer of the blue light emitting device with relatively low efficiency in multiple layers.

The light emitting device and the light emitting display device including the same according to the embodiment of the present disclosure can improve the efficiency of the light emitting layer, reduce the driving voltage and improve the lifespan. Therefore, the light emitting device and the light emitting display device including the same are continuously applicable, thus achieving ESG (environmental/social/governance) goals.

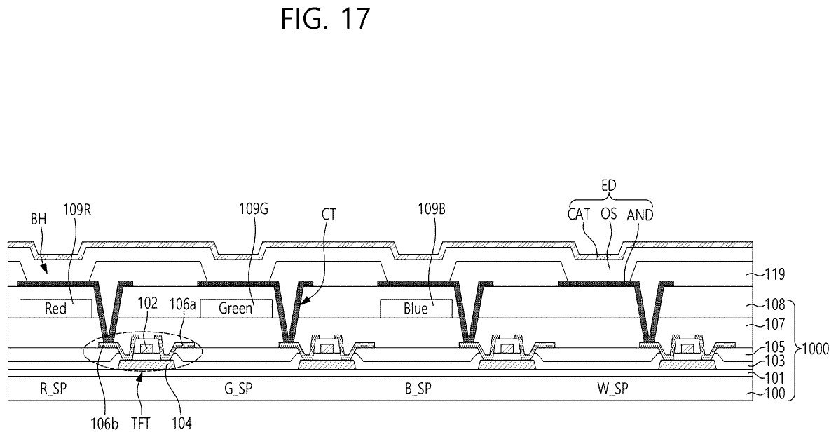

FIG. 17 is a cross-sectional view illustrating a light emitting display device according to one embodiment of the present disclosure.

As shown in FIG. 17, the light emitting display device according to an embodiment of the present disclosure can emit light through a first electrode AND on an emission side by applying the light emitting device described above to at least one of a plurality of subpixels R_SP, G_SP, B_SP, and W_SP.

The light emitting device ED of each subpixel can include a first electrode AND, a second electrode CAT, and an intermediate layer OS. The intermediate layer OS can include a plurality of stacks and have the same configuration in the plurality of subpixels R_SP, G_SP, B_SP, W_SP. In addition, the intermediate layer OS can include the electron transport stack between the plurality of stacks and the charge generation layer.

The light emitting display device according to an embodiment of the present disclosure can include a substrate 100 having a plurality of subpixels R_SP, G_SP, B_SP, W_SP, a light emitting device ED commonly provided on the substrate 100, a thin film transistor TFT provided on each of the subpixels R_SP, G_SP, B_SP, W_SP and connected to the first electrode AND of the light emitting device ED, and a color filter 109R, 109G, 109B provided under the first electrode AND of at least one of the subpixels.

The example in FIG. 17 shows a case in which a white subpixel W_SP is included in the light emitting display device, but the present disclosure is not limited thereto, and a structure in which the white subpixel W_SP is omitted and only red, green, and blue subpixels R_SP, G_SP, B_SP are provided can also be possible. In some cases, a combination of cyan subpixels, magenta subpixels, and yellow subpixels that can express white by replacing red, green, and blue subpixels is also possible.

The thin film transistor TFT includes, for example, a gate electrode 102, a semiconductor layer 104, and a source electrode 106a and a drain electrode 106b connected to both sides of the semiconductor layer 104. In addition, a channel protection layer can be further provided on an upper portion of a portion where a channel of the semiconductor layer 104 is located to prevent direct connection between the source/drain electrodes 106a, 106b and the semiconductor layer 104. A buffer layer 101 can be included on a substrate 100 and the thin film transistor TFT can be located on the buffer layer 101.

A gate insulating film 103 is provided between the gate electrode 102 and the semiconductor layer 104.

The semiconductor layer 104 can be formed of, for example, an oxide semiconductor, amorphous silicon, polycrystalline silicon, or a combination of two or more thereof. For example, when the semiconductor layer 104 is an oxide semiconductor, the heating temperature required to form a thin film transistor can be lowered, so that the substrate 100 can be used with a high degree of freedom, which makes it advantageous for application to a flexible display device.

A gate electrode 102 can be provided on the gate insulating film 103 and an interlayer insulating film 105 can be further provided between the gate electrode 102 and the source electrode 106a/drain electrode 106b.

In addition, the drain electrode 106b of the thin film transistor TFT can be connected to the first electrode AND and the contact hole CT provided in the first and second protective films 107 and 108.

The first protective film 107 is provided primarily to protect the thin film transistor TFT, and a color filter 109R, 109G, 109B can be provided on the first protective film 107.

A second protective film 108 is provided on the first protective film 107 including the color filter 109R, 109G, 109B.

When a plurality of subpixels includes a red subpixel R_SP, a green subpixel G_SP, a blue subpixel B_SP, and a white subpixel W_SP, as shown in FIG. 17, the color filters are provided as first to third color filters 109R, 109G, 109B for the remaining subpixels R_SP, G_SP, B_SP except for the white subpixel W_SP, so as to allow white light emitted through the first electrode AND to pass according to each wavelength. In addition, a second protective film 108 is formed under the first electrode AND to cover the first to third color filters 109R, 109G, 109B. The first electrode AND is formed on the surface of the second protective film 108 excluding the contact hole CT and is connected to one of the drain electrode 106b and the source electrode 106a of the thin film transistor TFT to receive an electrical signal from the thin film transistor TFT.

Here, the thin film transistor array substrate 1000 can include the substrate 100, the thin film transistor TFT, the color filter 109R, 109G, 109B, and the first and second protective films 107 and 108. A light emitting device ED can be disposed on the thin film transistor array substrate 1000.

The light emitting device ED is formed on a thin film transistor array substrate 1000 including a bank 119 defining a light emitting portion BH. The light emitting device ED can include a transparent first electrode AND, a second electrode CAT of a reflective electrode facing the first electrode AND, and a first common layer CML1 functioning to transport holes, a blue light emitting layer BEML, and a second common layer CML2 functioning to transport electrons, in at least one of the first and second blue stacks between the first electrode AND and the second electrode CAT, wherein the blue light emitting layer BEML can be formed as a multiple layer as described with reference to FIGS. 1 to 4. For example, the blue light emitting layer BEML can be divided into an odd number of layers having the same dopant and different hosts, wherein the odd layers contain a first host having a relatively high triplet energy level, and the even layers contain a second host having a relatively low triplet energy level. As a result, the TTF efficiency is increased in the even-numbered layers spaced apart from the two interfaces of the blue light emitting layer BEML, and the recombination region is separated by a predetermined distance from the interface of the blue light emitting layer BEML and the common layer, thereby preventing the reduction in the lifespan caused by the accumulation of excitons at the interface of the light emitting layer and the common layer, enabling the recycling of excitons by the TTF mechanism to be used for light emission, and providing increased efficiency and reduced operating voltage.

The first electrode AND is divided into each subpixel, and the remaining layers excluding the first electrode AND of the light emitting device ED can be provided as an integral part in the entire display area without distinction by subpixel.

Either the first electrode AND or the second electrode CAT can be connected to a thin film transistor TFT.

Meanwhile, the light emitting display device of FIG. 17 described above is illustrated as a structure in which light is emitted downward, but the present disclosure is not limited thereto. For example, when the first electrode AND includes a reflective electrode, the second electrode CAT is a transparent electrode or a reflective-transparent electrode, and the color filter is disposed above the second electrode CAT, the light emitting display device can implement top emission.

In the structure described above, the intermediate layer OS of the light emitting device ED is common to each subpixel, but the light emitting display device of the embodiment of the present disclosure is not limited thereto. For example, as described in the light emitting display device of FIG. 16, the light emitting layers can be formed separately from each other in the red, green, and blue subpixels.

A light emitting device according to one embodiment of the present disclosure can comprise a first electrode and a second electrode facing each other, a first common layer, a first light emitting layer and a second common layer between the first electrode and the second electrode. The first light emitting layer can be divided into an odd number of layers, odd-numbered layers of the first light emitting layer contain a first host and a first dopant, and the even-numbered layers of the first light emitting layer contain a second host and the first dopant. The first host can have a triplet energy level higher than that of the second host. The first common layer and the second common layer can contact a first layer and a last layer containing the first host and the first dopant, respectively.

In a light emitting device according to one embodiment of the present disclosure, a triplet energy level of the first dopant can be greater than a triplet energy level of the first host.

In a light emitting device according to one embodiment of the present disclosure, the first dopant contained in the first light emitting layer can be a fluorescent dopant having an emission peak at a wavelength of 430 nm to 495 nm.

In a light emitting device according to one embodiment of the present disclosure, the first common layer can comprise a hole transport layer contacting the first layer of the first light emitting layer and the second common layer comprises an electron transport layer contacting the last layer of the first light emitting layer. A LUMO energy level of the first dopant can be higher than a LUMO energy level of each of the first and second hosts. The hole transport layer can have a LUMO energy level higher than the LUMO energy level of the first dopant and a HOMO energy level lower than the HOMO energy level of the first dopant. The electron transport layer can have a LUMO energy level lower than the LUMO energy level of the first dopant.

In a light emitting device according to one embodiment of the present disclosure, the HOMO energy level of the first dopant can be higher than the HOMO energy level of each of the first and second hosts.

A light emitting device according to one embodiment of the present disclosure can further comprise a charge generation layer, a third common layer, a second light emitting layer, and a fourth common layer sequentially disposed between the second common layer and the second electrode. The second light emitting layer can emit light with the same color as the first light emitting layer.

In a light emitting device according to one embodiment of the present disclosure, the second light emitting layer can be divided into an odd number of layers. The odd-numbered layers of the second light emitting layer can contain a third host and a second dopant and the even-numbered layers of the second light emitting layer can contain a fourth host and the second dopant. The third host can have a triplet energy level higher than that of the fourth host. The third common layer and the fourth common layer can contact the first layer and the last layer having the third host and the second dopant, respectively.

In a light emitting device according to one embodiment of the present disclosure, the first dopant and the second dopant can be the same.

In a light emitting device according to one embodiment of the present disclosure, a thickness of the last layer of the second light emitting layer contacting the fourth common layer can be less than a thickness of the last layer of the first light emitting layer contacting the second common layer.

In a light emitting device according to one embodiment of the present disclosure, the thickness of the last layer of the second light emitting layer contacting the fourth common layer can be less than the thickness of the even-numbered layer contacting the last layer of the second light emitting layer.

In a light emitting device according to one embodiment of the present disclosure, the last layer of the second light emitting layer contacting the fourth common layer can be thinner than the first layer of the second light emitting layer contacting the third common layer.

In a light emitting device according to one embodiment of the present disclosure, an intensity of light emitted from the first light emitting layer can be the strongest at an interface between the first layer contacting the first common layer and an even-numbered layer contacting the first layer contacting the first common layer. The intensity of light emitted from the second light emitting layer can be the strongest at the interface between the first layer contacting the third common layer and the even-numbered layer contacting the first layer contacting the third common layer.

In a light emitting device according to one embodiment of the present disclosure, a total thickness of the first light emitting layer can be the same as a total thickness of the second light emitting layer.

In a light emitting device according to one embodiment of the present disclosure, a content of the first dopant of the odd-numbered layer can be the same as a content of the first dopant of the even-numbered layer in the first light emitting layer. A content of the second dopant of the odd-numbered layer can be the same as a content of the second dopant of the even-numbered layer in the second light emitting layer.

In a light emitting device according to one embodiment of the present disclosure, in the second light emitting layer, a thickness of the even-numbered layer can be more than a thickness of the odd-numbered layer contacting the even-numbered layer.

A light emitting device according to one embodiment of the present disclosure can further comprise a charge generation layer, a third common layer, a second light emitting layer, and a fourth common layer sequentially disposed between the second common layer and the second electrode. The second light emitting layer can be a light emitting layer that emits light with a different color from a light emitted from the first light emitting layer.

A light emitting display device according to one embodiment of the present disclosure can comprise a substrate including a plurality of subpixels, a pixel circuit provided in each of the plurality of subpixels and the light emitting device connected to a thin film transistor of the pixel circuit.

A light emitting display device according to one embodiment of the present disclosure can comprise a substrate including a blue subpixel, a green subpixel, and a red subpixel, a pixel circuit provided at each of the blue subpixel, the green subpixel, and the red subpixel, a first electrode connected to a thin film transistor of the pixel circuit at each of the blue subpixel, the green subpixel, and the red subpixel, a second electrode facing the first electrode and a first common layer and a second common layer between the first electrode and the second electrode.

The blue subpixel can comprise a first blue light emitting layer containing a blue dopant between the first common layer and the second common layer.

The green subpixel can comprise a first green light emitting layer containing a green dopant between the first common layer and the second common layer.

The red subpixel can comprise a first red light emitting layer containing a red dopant between the first common layer and the second common layer.

The first blue light emitting layer can be divided into an odd number of layers, odd-numbered layers of the first blue light emitting layer contain a first blue host and a first blue dopant, and even-numbered layers of the first blue light emitting layer contain a second blue host and the first blue dopant. The first blue host can have a triplet energy level higher than that of the second blue host.

The first common layer and the second common layer at the blue subpixel can contact a first layer and a last layer containing a first blue host and a first blue dopant, respectively.

A light emitting display device according to one embodiment of the present disclosure can further comprise a charge generation layer, a third common layer, a second light emitting layer, and a fourth common layer sequentially disposed between the second common layer and the second electrode.

The second light emitting layer can comprise a second blue light emitting layer at the blue subpixel, a second green light emitting layer at the green subpixel, and a second red light emitting layer at the red subpixel.

The second blue light emitting layer can be divided into an odd number of layers, odd-numbered layers of the second blue light emitting layer contain a third blue host and a second blue dopant, and even-numbered layers of the second blue light emitting layer contain a fourth blue host and the second blue dopant. The third blue host can have a triplet energy level higher than that of the fourth blue host.

The third common layer and the fourth common layer at the blue subpixel can contact the first layer and the last layer containing the third blue host and the second blue dopant, respectively.

In a light emitting display device according to one embodiment of the present disclosure, a thickness of the last layer of the second blue light emitting layer contacting the fourth common layer can be less than a thickness of the last layer of the first blue light emitting layer contacting the second common layer.

In a light emitting display device according to one embodiment of the present disclosure, the last layer of the second blue light emitting layer contacting the fourth common layer can be thinner than an even-numbered layer contacting the last layer of the second blue light emitting layer.

In a light emitting display device according to one embodiment of the present disclosure, the last layer contacting the fourth common layer in the second light emitting layer can be thinner than the first layer contacting the third common layer.

The light emitting device of the present disclosure and the light emitting display device including the same have the following effects.

The light emitting device according to the embodiments of the present disclosure is formed so that the host layers are disposed alternately and the number of light emitting layers is odd so that the host of the first layer is the same as that of the last layer in the light emitting layer. In addition, the odd layer of the light emitting layer contains a host having a high triplet energy level, and the even layer of the light emitting layer contains a host having a low triplet energy level. As a result, the delayed fluorescence efficiency by the TTF mechanism is increased in the inner even layer of the light emitting layer disposed inside the first layer and the last layer located at both interfaces of the light emitting layer and not contacting both interfaces of the light emitting layer, thereby improving the light emitting efficiency and enhancing the efficiency of the light emitting device and the light emitting display device.

The lifespan of the light emitting device and the light emitting display device including the same can be effectively improved by reducing the quenching ratio of the excitons generated in the light emitting layer and increasing the ratio used for direct or delayed light emission.

When the blue light emitting layer of the blue light emitting device has a multiple layer structure, it is possible to prevent an increase in the driving voltage and improve the lifespan by adjusting the thickness of the first layer and the last layer.

The light emitting device and light emitting display device including the same according to the embodiments of the present disclosure can improve the efficiency of the light emitting layer, thereby reducing the driving voltage and improving the lifespan. Accordingly, the light emitting device and the light emitting display device are continuously applicable, thus achieving ESG (environmental/social/governance) goals.

It will be apparent to those skilled in the art that various modifications and variations can be made in the present disclosure without departing from the spirit or scope of the inventions. Thus, it is intended that the present disclosure covers the modifications and variations of this invention provided they come within the scope of the appended claims and their equivalents.

What is claimed is:

1. A light emitting device comprising:
a first electrode and a second electrode facing each other; and
a first common layer, a first light emitting layer and a second common layer disposed between the first electrode and the second electrode,
wherein the first light emitting layer is divided into an odd number of layers,
odd-numbered layers of the first light emitting layer contain a first host and a first dopant,
even-numbered layers of the first light emitting layer contain a second host and the first dopant,
the first host has a triplet energy level higher than a triple energy level of the second host, and
the first common layer and the second common layer contact a first layer and a last layer containing the first host and the first dopant, respectively.

2. The light emitting device according to claim 1, wherein a triplet energy level of the first dopant is greater than the triplet energy level of the first host.

3. The light emitting device according to claim 1, wherein the first dopant contained in the first light emitting layer includes a fluorescent dopant having an emission peak at a wavelength of 430 nm to 495 nm.

4. The light emitting device according to claim 1, wherein the first common layer comprises a hole transport layer contacting the first layer of the first light emitting layer, and the second common layer comprises an electron transport layer contacting the last layer of the first light emitting layer,
a lowest unoccupied molecular orbital (LUMO) energy level of the first dopant is higher than a LUMO energy level of each of the first and second hosts,
the hole transport layer has a LUMO energy level higher than the LUMO energy level of the first dopant and has a highest occupied molecular orbital (HOMO) energy level lower than the HOMO energy level of the first dopant, and
the electron transport layer has a LUMO energy level lower than the LUMO energy level of the first dopant.

5. The light emitting device according to claim 1, wherein a highest occupied molecular orbital (HOMO) energy level of the first dopant is higher than a HOMO energy level of each of the first and second hosts.

6. The light emitting device according to claim 1, further comprising a charge generation layer, a third common layer, a second light emitting layer, and a fourth common layer sequentially disposed between the second common layer and the second electrode,
wherein the second light emitting layer is configured to emit light of a same color as the first light emitting layer.

7. The light emitting device according to claim 6, wherein the second light emitting layer is divided into an odd number of layers,
odd-numbered layers of the second light emitting layer contain a third host and a second dopant, and even-numbered layers of the second light emitting layer contain a fourth host and the second dopant,
the third host has a triplet energy level higher than a triplet energy level of the fourth host, and
the third common layer and the fourth common layer contact the first layer and the last layer having the third host and the second dopant, respectively.

8. The light emitting device according to claim 7, wherein the first dopant and the second dopant are the same.

9. The light emitting device according to claim 7, wherein a thickness of the last layer of the second light emitting layer contacting the fourth common layer is less than a thickness of the last layer of the first light emitting layer contacting the second common layer.

10. The light emitting device according to claim 7, wherein a thickness of the last layer of the second light emitting layer contacting the fourth common layer is less than a thickness of the even-numbered layer contacting the last layer of the second light emitting layer.

11. The light emitting device according to claim 7, wherein the last layer of the second light emitting layer contacting the fourth common layer is thinner than the first layer of the second light emitting layer contacting the third common layer.

12. The light emitting device according to claim 11, wherein an intensity of light emitted from the first light emitting layer is strongest at an interface between the first layer contacting the first common layer and an even-numbered layer contacting the first layer contacting the first common layer, and
an intensity of light emitted from the second light emitting layer is strongest at an interface between the first layer contacting the third common layer and the even-numbered layer contacting the first layer contacting the third common layer.

13. The light emitting device according to claim 6, wherein a total thickness of the first light emitting layer is same as a total thickness of the second light emitting layer.

14. The light emitting device according to claim 7, wherein a content of the first dopant of the odd-numbered layer is same as a content of the first dopant of the even-numbered layer in the first light emitting layer, and
a content of the second dopant of the odd-numbered layer is same as a content of the second dopant of the even-numbered layer in the second light emitting layer.

15. The light emitting device according to claim 7, wherein in the second light emitting layer, a thickness of the even-numbered layer is more than a thickness of the odd-numbered layer contacting the even-numbered layer.

16. The light emitting device according to claim 1, further comprising a charge generation layer, a third common layer, a second light emitting layer, and a fourth common layer sequentially disposed between the second common layer and the second electrode,
wherein the second light emitting layer is a light emitting layer configured to emit light of a different color from a light emitted from the first light emitting layer.

17. A light emitting display device comprising:
a substrate including a blue subpixel, a green subpixel, and a red subpixel;
a pixel circuit provided at each of the blue subpixel, the green subpixel, and the red subpixel;
a first electrode connected to a thin film transistor of the pixel circuit at each of the blue subpixel, the green subpixel, and the red subpixel;
a second electrode facing the first electrode; and
a first common layer and a second common layer between the first electrode and the second electrode,
wherein the blue subpixel comprises a first blue light emitting layer containing a blue dopant between the first common layer and the second common layer,
the green subpixel comprises a first green light emitting layer containing a green dopant between the first common layer and the second common layer,
the red subpixel comprises a first red light emitting layer containing a red dopant between the first common layer and the second common layer,
the first blue light emitting layer is divided into an odd number of layers,
odd-numbered layers of the first blue light emitting layer contain a first blue host and a first blue dopant,
even-numbered layers of the first blue emitting layer contain a second blue host and the first blue dopant,
the first blue host has a triplet energy level higher than a triplet energy level of the second blue host, and
the first common layer and the second common layer at the blue subpixel contact a first layer and a last layer containing a first blue host and a first blue dopant, respectively.

18. The light emitting display device according to claim 17, further comprising a charge generation layer, a third common layer, a second light emitting layer, and a fourth common layer sequentially disposed between the second common layer and the second electrode, wherein:
the second light emitting layer comprises a second blue light emitting layer at the blue subpixel, a second green light emitting layer at the green subpixel, and a second red light emitting layer at the red subpixel,
the second blue light emitting layer is divided into an odd number of layers, odd-numbered layers of the second blue light emitting layer contain a third blue host and a second blue dopant, and even-numbered layers of the second blue light emitting layer contain a fourth blue host and the second blue dopant,
the third blue host has a triplet energy level higher than a triplet energy level of the fourth blue host, and
the third common layer and the fourth common layer at the blue subpixel contact the first layer and the last layer containing the third blue host and the second blue dopant, respectively.

19. The light emitting display device according to claim 18, wherein a thickness of the last layer of the second blue light emitting layer contacting the fourth common layer is less than a thickness of the last layer of the first blue light emitting layer contacting the second common layer.

20. The light emitting display device according to claim 18, wherein the last layer of the second blue light emitting layer contacting the fourth common layer is thinner than an even-numbered layer contacting the second blue light emitting layer, and
the last layer contacting the fourth common layer in the second light emitting layer is thinner than the first layer contacting the third common layer.
